(19) United States
(12) Patent Application Publication
(10) Pub. No.: US 2019/0288006 A1
(43) Pub. Date: Sep. 19, 2019

(54) Backside Charge Control for FET Integrated Circuits

(71) Applicant: pSemi Corporation, San Diego, CA (US)

(72) Inventors: Abhijeet Paul, Poway, CA (US); Simon Edward Willard, Irvine, CA (US); Hiroshi Yamada, San Diego, CA (US); Alain Duvallet, San Diego, CA (US)

(21) Appl. No.: 16/297,402

(22) Filed: Mar. 8, 2019

Related U.S. Application Data
(63) Continuation-in-part of application No. 15/920,321, filed on Mar. 13, 2018.

(51) Int. Cl. H01L 27/12; H01L 29/78; H01L 49/02; H01L 21/84

(52) U.S. Cl. CPC H01L 27/1203; H01L 29/7831; H01L 28/20; H01L 28/10; H01L 21/84; H01L 28/40

(57) ABSTRACT

Semiconductor-on-insulator field effect transistor (FET) integrated circuit (IC) structures and fabrication processes that mitigate or eliminate the problems caused by the secondary parasitic back-channel FET of conventional semiconductor-on-insulator FET IC structures. Embodiments enable full control of the secondary parasitic back-channel FET of semiconductor-on-insulator IC primary FETs. Embodiments include taking partially fabricated ICs made using a process which allows access to the back side of the FET, such as “single layer transfer” process, and then fabricating a conductive aligned supplemental (CAS) gate structure relative to the insulating layer juxtaposed to a primary FET such that a control voltage applied to the CAS gate can regulate the electrical characteristics of the regions of the primary FET adjacent the insulating layer. The IC structures present as a four or five terminal device: source S, drain D, primary gate G, CAS gate, and, optionally, a body contact.

### CROSS-REFERENCE TO RELATED APPLICATIONS

The present continuation-in-part application claims priority to the following patent application, assigned to the assignee of the present invention, the contents of which are incorporated by reference: U.S. patent application Ser. No. 15/920,321, filed Mar. 13, 2018, entitled “Semiconductor-On-Insulator Transistor with Improved Breakdown Characteristics”.

### BACKGROUND

### Technical Field

This invention relates to electronic integrated circuits, and more particularly to electronic integrated circuits having transistors fabricated with semiconductor-on-insulator technology.

### Background

Virtually all modern electronic products—including laptop computers, mobile telephones, and electric cars—utilize complementary metal oxide semiconductor (CMOS) transistor integrated circuits (ICs), and in many cases CMOS ICs fabricated using a semiconductor-on-in-sulator process, such as silicon-on-insulator (SOI) or germanium-on-insulator. SOI transistors in which the electrical insulator is aluminum oxide (i.e., sapphire) are called silicon-on-sapphire or “SOS” devices. Another example of a semiconductor-on-insulator technology is “silicon-on-glass”, and other examples are known to those of ordinary skill in the art.

Taking SOI as one example of semiconductor-on-insulator, SOI technology encompasses the use of a layered silicon-insulator-silicon substrate in place of conventional “bulk” silicon substrates in semiconductor manufacturing. More specifically, SOI transistors are generally fabricated on a layer of silicon dioxide, SiO2 (often called a “buried oxide” or “BOX” layer), which in turn is formed on a bulk silicon substrate. The BOX layer reduces certain parasitic effects typical of bulk silicon CMOS processes, thereby improving performance. SOI-based devices thus differ from conventional bulk silicon devices in that the silicon regions of the CMOS transistors are fabricated on an electrical insulator (typically silicon dioxide or aluminum oxide) rather than on a bulk silicon substrate.

As a specific example of a semiconductor on insulator process for fabricating ICs, FIG. 1A is a stylized cross-sectional view of a typical prior art SOI IC structure 100 for a single field effect transistor (FET). The SOI structure 100 includes a substrate 102, a buried-oxide (BOX) insulator layer 104, and an active layer 106 (note that the dimensions for the elements of the SOI IC structure 100 are not to scale; some dimensions have been exaggerated for clarity or emphasis). The substrate 102 is typically a semiconductor material such as silicon. The BOX layer 104 is a dielectric, and is often silicon dioxide formed as a “top” surface 102T of the silicon substrate 102, such as by oxidation, layer transfer, or implantation. The active layer 106 may include some combination of implants and/or layers that include dopants, dielectrics, polysilicon, metal wiring, passivation, and other materials to form active and/or passive electronic components and/or mechanical structures. For example, in the illustrated embodiment, a FET (encircled by a dashed oval 108) is shown, with the FET 108 comprising a source S, a drain D, and a primary gate G atop an insulating gate oxide (GOX) layer 110. A body B is defined below the primary gate G, between the source S and the drain D. In operation, a “conduction channel” or an “inversion channel” is generated within the body B between the source S and the drain D and proximate the GOX layer 110 (e.g., within about the top 100A of the body B). A body contact (not shown), which generally comprises a region with the same doping as the body B, may be resistively coupled to the body B through an extension of the semiconductor island typically extending in the width direction of the transistor (in FIG. 1A, that would be in/out of the plane of the image) to provide a fourth terminal to the FET 108. As is known, the body contact is commonly coupled to a bias node such as a power supply, to circuit ground, or to the source S (although other connection nodes are possible). If an SOI transistor has a body contact, it is known as body-contacted transistor, otherwise it is known as a floating-body transistor.

If the source S and drain D are highly doped with N type material, the FET is an N-type FET. Conversely, if the source S and drain D are highly doped with P type material, the FET is a P-type FET. Thus, the source S and drain D doping type determines whether a FET is an N-type or a P-type. CMOS devices comprise N-type and P-type FETs co-fabricated on a single IC die, in known fashion.

A superstructure 112 of various elements, regions, and structures may be fabricated in known fashion above the FET 108 in order to implement particularly functionality. The superstructure 112 may include, for example, conductive interconnections from the illustrated FET 108 to other components (including other FETs) and/or external contacts, passivation layers and regions, and protective coatings. The conductive interconnections may be, for example, copper or other suitable metal or electrically conductive material.

For example, FIG. 1B is a stylized cross-sectional view of a typical prior art SOI IC structure 120 for a single FET, showing details of the superstructure 112. In this example, the superstructure 112 includes conductive (e.g., metal) interconnect levels M1 (closest to the FET 108), M2, M3, M4, and a Top Metal layer, separated in places by insulating and/or passivation layers or regions 116a, 116b. The conductive interconnect levels M1, M2, M3, M4, Top Metal layer, etc., are typically formed within a CMOS fabrication facility. The Top Metal layer may be covered in whole or in part by another conductive material (commonly aluminum) to form what is commonly known as a “redistribution layer”, or RDL, shown in FIG. 1B as within a sub-portion 112′ of the superstructure 112. Top-side RDLs are generally added after wafers have completed the CMOS fabrication process and are often of much thicker and wider dimensions than the CMOS metallization (e.g., M1, M2, M3, M4, and Top Metal layer). Top-side RDLs are often used to distribute high current power around an IC chip or to render high-Q inductors (and sometimes capacitors) for RF circuits. As can be seen in FIG. 1B, top-side RDLs are often connected to the Top Metal of the IC for subsequent packaging. An aluminum layer may also be used as a capping layer over final copper metal structures, which generally cannot be left exposed in order to avoid oxidation of the copper. Thus, an aluminum layer may be both an RDL and a capping layer.

Other elements, regions, and structures may be included for particular circuit designs. For example, referring to FIG. 1A, conductive substrate contact (S-contacts) (shown as the structure “SC”) may be formed from the superstructure 112 through the active layer 106 to the BOX layer 104 or to conductive regions or wells formed in and/or above the BOX layer 104. S-contacts may be used, for example, to mitigate accumulated charge effects that adversely affect the FET, for shielding, and/or for thermal conduction. Examples of applications of S-contacts are set forth in U.S. Pat. No. 9,837,412, issued Dec. 5, 2017, entitled “S-Contact for SOI”, in U.S. Pat. No. 9,960,098, issued May 1, 2018, entitled “Systems and Methods for Thermal Conduction Using S-Contacts”, and in U.S. patent application Ser. No. 15/600,588, filed May 19, 2017, entitled “Managed Substrate Effects for Stabilized SOI FETs”, all of which are hereby incorporated by reference.

As should be appreciated by one of ordinary skill in the art, a single IC die may embody from one FET 108 to millions of FETs 108. Further, the various elements of the superstructure 112 may extend in three-dimensions and have quite complex shapes. In general, the details of the superstructure 112 will vary from IC design to IC design.

The BOX layer 104, while enabling many beneficial characteristics for SOI IC's, also introduces some problems, such as capacitive coupling to the substrate 102, a thermal barrier to heat flow, and a voltage breakdown path to the substrate 102. Capacitive coupling with the substrate 102 alone can cause numerous side effects compared to an ideal SOI transistor, such as increased leakage current, lower breakdown voltage, signal cross-coupling, and linearity degradation. However, the most serious capacitive coupling effect caused by the BOX layer 104 is often the “back-channel” effect.

Referring to FIG. 1A, the structure of a secondary parasitic back-channel FET (shown in a dashed square 120) is formed by the source S, the drain D, the BOX layer 104 (functioning as a gate insulator), and the substrate 102 (effectively functioning as a secondary gate). FIG. 1C is an equivalent schematic diagram of the FET structure shown in FIG. 1A, and shows how the secondary parasitic back-channel FET 120 is coupled in parallel with the primary FET 108. Notably, the voltages and charge accumulations in and around the secondary gate (i.e., the substrate 102) may vary and in general are not well controlled. Accordingly, as is widely known, the presence of the secondary parasitic back-channel FET 120 adjacent the FET 108 can place the bottom of the FET 108 in uncontrolled states, often in a subthreshold leakage regime, which in turn may create uncontrollable source-drain leakage currents.

It is possible to mitigate some of the side effects of the secondary parasitic back-channel FET 120. One known mitigating technique utilizes “single layer transfer”, or SLT, as part of the IC fabrication process. The SLT process essentially flips an entire SOI transistor structure upside down onto a “handle wafer”, with the original substrate (e.g., substrate 102 in FIG. 1A) then being removed, thereby eliminating the substrate 102. For example, FIG. 2 is a stylized cross-sectional view of a typical prior art SOI IC structure 200 for a single FET, fabricated using an SLT process. Essentially, after most or all of the superstructure 112 of FIG. 1A is completed (some layers may be omitted, such as some metallic contacts), a first passivation layer 202 is generally applied on top of the superstructure 112, and then the original substrate 102 and the layers denoted as “X” in FIG. 1A are flipped over and bonded in known fashion to a handle wafer 204, as shown in FIG. 2. Thereafter, the original substrate 102 is removed by mechanical and/or chemical means, exposing the BOX layer 104. A non-conductive second passivation layer 206, which may be a conventional interlayer dielectric (ILD) material, may be formed on the exposed BOX layer 104.

In the structure of FIG. 2, the portions of the FET 108 formerly closest to the original substrate 102 are now found near the “new top” of the IC structure, farthest away from the handle wafer 204. Conversely, those portions of the FET 108 formerly farthest away from the original substrate 102 are now found at the bottom of the IC structure, closest to the handle wafer 204. Thus, the BOX layer 104 in the structure of FIG. 1A was adjacent to the original substrate 102 before the SLT process. Although not exactly to scale, the BOX layer 104 in FIG. 1A exhibits relatively high capacitive coupling to the original substrate 102, causing the above-mentioned side effects. Referring to FIG. 2, while the BOX layer 104 is still present with the inverted IC structure, the “backside” of the FET 108 is now near the new top of the IC structure with no adjacent semiconductive “gate” material (i.e., the original substrate 102).

While the IC structure of FIG. 2 may be preferred to the closely coupled substrate IC structure of FIG. 1A, where the original substrate 102 serves as a gate for the secondary parasitic back-channel FET 120, the electrical characteristics of the regions of the FET 108 adjacent the BOX layer 104 are still not well controlled.

While SOI FETs have been used in the examples above, similar problems exist in other semiconductor-on-insulator technologies.

Accordingly, there is a need for a FET IC structure that mitigates or eliminates the problems caused by the secondary parasitic back-channel FET 120 of conventional FET IC structures. The present invention addresses this need and more.

### SUMMARY

The present invention encompasses semiconductor-on-insulator field effect transistor (FET) integrated circuit (IC) structures and fabrication processes that mitigate or eliminate the problems caused by the secondary parasitic back-channel FET of conventional semiconductor-on-insulator FET IC structures. Embodiments of the current invention enable full control of the secondary parasitic back-channel FET of semiconductor-on-insulator IC primary FETs.

In essence, embodiments of the invention take advantage of the existence of the secondary parasitic back-channel FET of semiconductor-on-insulator IC primary FETs by fabricating such ICs using a process which allows access to the backside of the FET, such as a “single layer transfer” (SLT) process (collectively, a “backside access process”). Thereafter, a conductive aligned supplemental (CAS) gate structure is fabricated relative to the BOX layer juxtaposed to a primary FET such that a control voltage applied to the CAS gate can regulate the electrical characteristics of the regions of the primary FET adjacent the BOX layer.

A CAS gate is separated from the backside of a corresponding primary FET by the BOX layer and/or a protective layer formed as part of the backside access process. Accordingly, the BOX layer and/or the protective layer function as gate dielectric material for the CAS gate. The CAS gate, the gate dielectric material (i.e., BOX layer and/or the protective layer) between the CAS gate and the body B of the primary FET, and the source S and drain D of the primary FET, forms a controllable MOSFET, with independent control provided by the CAS gate. This is in contrast with—and replaces—the formerly present but uncontrolled secondary parasitic back-channel FET. The IC structures thus present as a four or five terminal device: source S, drain D, primary gate G, CAS gate, and, optionally, a body contact.

By applying control voltages to a CAS gate (typically DC voltages), various effects can be induced in and around the body B of the corresponding primary FET, depending on the type of transistor originally made in the semiconductor-on-insulator structure. For example, FETs that include a CAS gate have a higher voltage capability than conventional FETs due to the ability to bias the CAS gate such that the body B is more depleted than can be accomplished by the primary gate G alone. As another example, FETs that include a CAS gate have a lower ON resistance (R_{ON}) than conventional FETs due to the ability to bias the CAS gate such that the body B is more enhanced than can be accomplished by the primary gate G alone, resulting in lower insertion loss as well as a higher current capacity without increasing heat generation. As yet another example, FETs that include a CAS gate may have lower leakage currents in subthreshold operating conditions due to the ability to bias the back-channel region of the body B in a fully OFF condition. Notably, all of these benefits are available from the same FET under different operating conditions, just by varying the bias voltage applied to its CAS gate.

In some embodiments, CAS gates are formed as part of a redistribution layer (RDL). In other embodiments, CAS gates are typically formed using fine-line conductor fabrication techniques before the RDL stage.

The details of one or more embodiments of the invention are set forth in the accompanying drawings and the description below. Other features, objects, and advantages of the invention will be apparent from the description and drawings, and from the claims.

### DESCRIPTION OF THE DRAWINGS

FIG. 1A is a stylized cross-sectional view of a typical prior art SOI IC structure for a single field effect transistor (FET).

FIG. 1B is a stylized cross-sectional view of a typical prior art SOI IC structure for a single FET, showing details of the superstructure.

FIG. 1C is an equivalent schematic diagram of the FET structure shown in FIG. 1A, and shows how the secondary parasitic back-channel FET is coupled in parallel with the primary FET.

FIG. 2 is a stylized cross-sectional view of a typical prior art SOI IC structure for a single FET, fabricated using an SLT process.

FIG. 3A is a stylized cross-sectional view of an SOI IC structure for a single primary FET, showing a conductive aligned supplemental (CAS) gate formed after application of a backside access process, such as an SLT process.

FIG. 3B is a simplified IC structure corresponding to the IC structure of FIG. 3A, redrawn for enhanced clarity of the various structural elements, with the scale of selected elements enlarged relative to other elements for emphasis.

FIG. 4A is a stylized cross-sectional view of a partial SOI IC structure for a single primary FET, showing the results of a conventional fabrication process up to (but generally not including) application of a redistribution layer (RDL) on the top of the IC structure.

FIG. 4B is a stylized cross-sectional view of a partial SOI IC structure comprising the partial SOI IC structure of FIG. 4A and an added passivation layer formed on the exposed top surface of the superstructure.

FIG. 4C is a stylized cross-sectional view of a partial SOI IC structure comprising the partial SOI IC structure of FIG. 4B after application of a “single layer transfer” (SLT) process.

FIG. 4D is a stylized cross-sectional view of a partial SOI IC structure comprising the partial SOI IC structure of FIG. 4C with added structures and modifications.

FIG. 4E is a stylized cross-sectional view of a partial SOI IC structure comprising the partial SOI IC structure of FIG. 4D with added structures and modifications.

FIG. 4F is a stylized cross-sectional view of a partial SOI IC structure comprising the partial SOI IC structure of FIG. 4E with added structures and modifications.

FIG. 4G is a stylized cross-sectional detailed view of the primary FET and CAS gate of FIG. 4F, omitting the other structures shown in FIG. 4F for clarity.

FIG. 5 is a graph of drain-source current (on a log10 scale) of a CAS-gated FET as a function of primary gate-source voltage, for different values of CAS secondary gate control voltages.

FIG. 6 is a process flow diagram of a first method for making a transistor device.

FIG. 7 is a process flow diagram of a second method for making a transistor device.

FIG. 8 is a process flow diagram of a third method for making a transistor device.

FIG. 9 is a stylized cross-sectional view of a CAS-gated FET having a relatively coarse CAS gate formed in a patterned backside contact pattern (BCP) of an RDL layer.

FIG. 10A shows a top view of an IC structure that includes two 7-FET stacks of CAS-gated FETs formed with fine conductive lines.

FIG. 10B is a cross-sectional view of the IC structure taken along line A-A for the innermost five of the FETs of FIG. 10A.

FIG. 10C is a cross-sectional view of the IC structure taken along line B-B for the innermost five of the FETs of FIG. 10A.

FIG. 11 shows a top view of an IC structure that illustrates a first type of misalignment mitigation structure for FCL CAS-gated FETs with respect to TBC's.

FIG. 12 shows a top view of an IC structure that illustrates a second type of misalignment mitigation structure for FCL CAS-gated FETs with respect to TBC's.

FIG. 13 shows a top view of an IC structure that illustrates a third type of misalignment mitigation structure for FCL CAS-gated FETs with respect to TBC's.

FIG. 14 is a top view of a stylized integrated circuit having distinct sub-circuit regions.

FIG. 15 is a process flow diagram of a first method for fabricating an integrated circuit structure having FCL CAS-gated FETs.

FIG. 16 is a process flow diagram of a second method for fabricating an integrated circuit structure having FCL CAS-gated FETs.

Like reference numbers and designations in the various drawings indicate like elements.

### DETAILED DESCRIPTION

The present invention encompasses semiconductor-on-insulator field effect transistor (FET) integrated circuit (IC) structures and fabrication processes that mitigate or eliminate the problems caused by the secondary parasitic back-channel FET of conventional semiconductor-on-insulator FET IC structures. Embodiments of the current invention enable full control of the secondary parasitic back-channel FET of semiconductor-on-insulator IC primary FETs.

Overview of Basic Structure

In essence, embodiments of the invention take advantage of the existence of the secondary parasitic back-channel FET of semiconductor-on-insulator IC primary FETs by fabricating such ICs using a process which allows access to the backside of the FET, such as a “single layer transfer” (SLT) process (collectively, a “backside access process”). Thereafter, a conductive aligned supplemental (CAS) gate structure is fabricated relative to the BOX layer juxtaposed to a primary FET such that a control voltage applied to the CAS gate can regulate the electrical characteristics of the regions of the primary FET adjacent the BOX layer 104.

For simplicity, the following examples of embodiments of the invention utilize silicon-on-insulator (SOI) fabrication technology as one example of semiconductor-on-insulator fabrication techniques. However, it should be understood that the methods, structures, and circuits described below apply generally to other semiconductor-on-insulator fabrication technologies and devices.

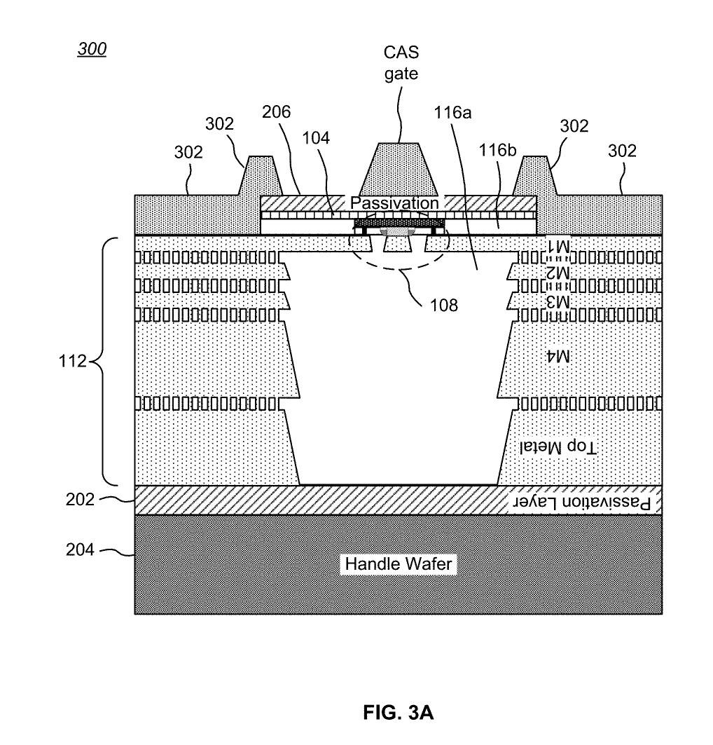

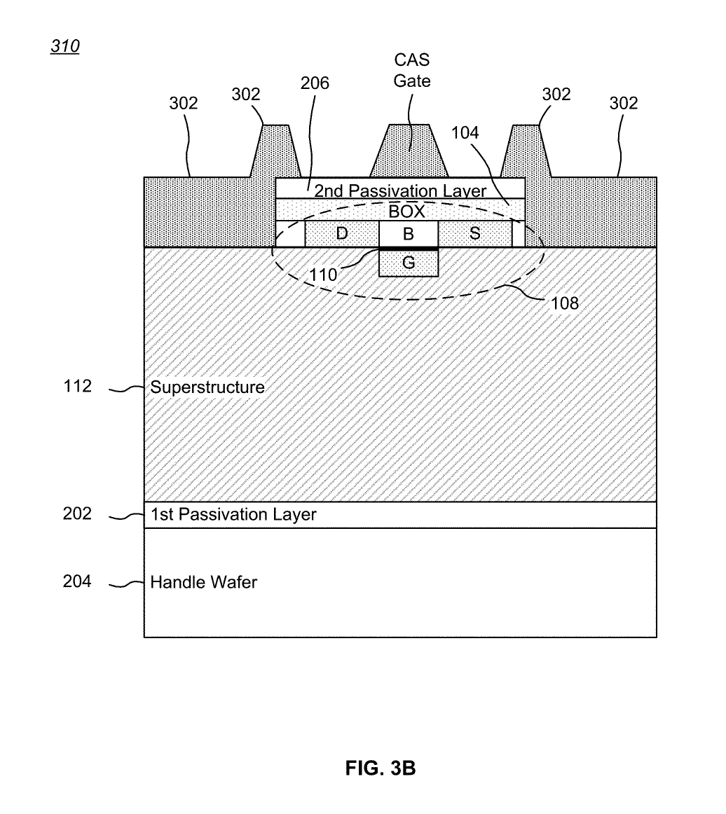

FIG. 3A is a stylized cross-sectional view of an SOI IC structure 300 for a single primary FET 108, showing a conductive aligned supplemental (CAS) gate formed after application of a backside access process, such as an SLT process. FIG. 3B is a simplified IC structure 310 essentially corresponding to the IC structure 300 of FIG. 3A, redrawn for enhanced clarity of the various structural elements, with the scale of selected elements enlarged relative to other elements for emphasis.

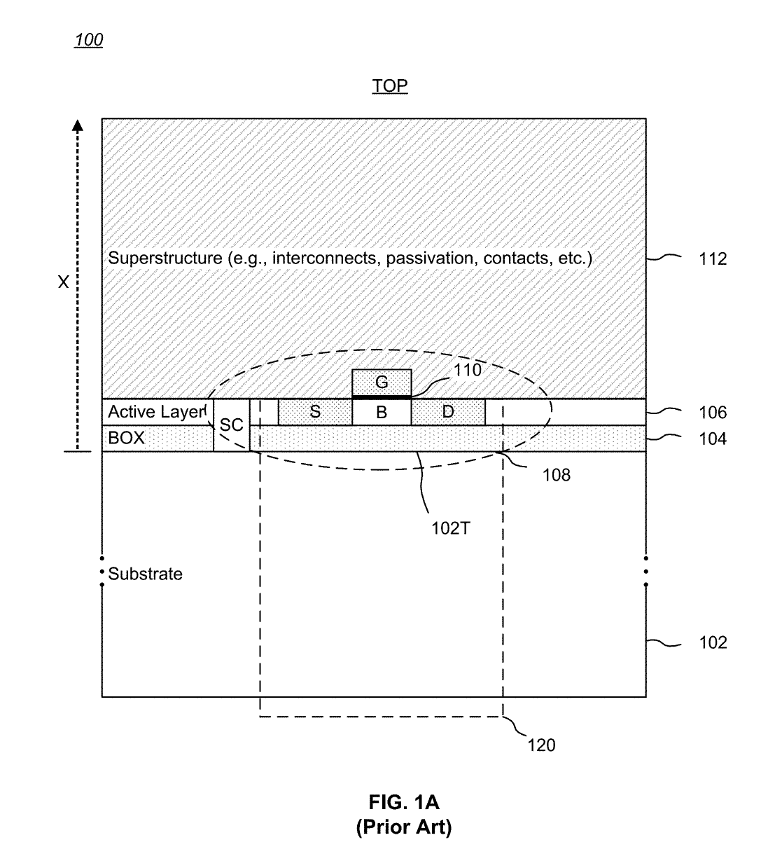

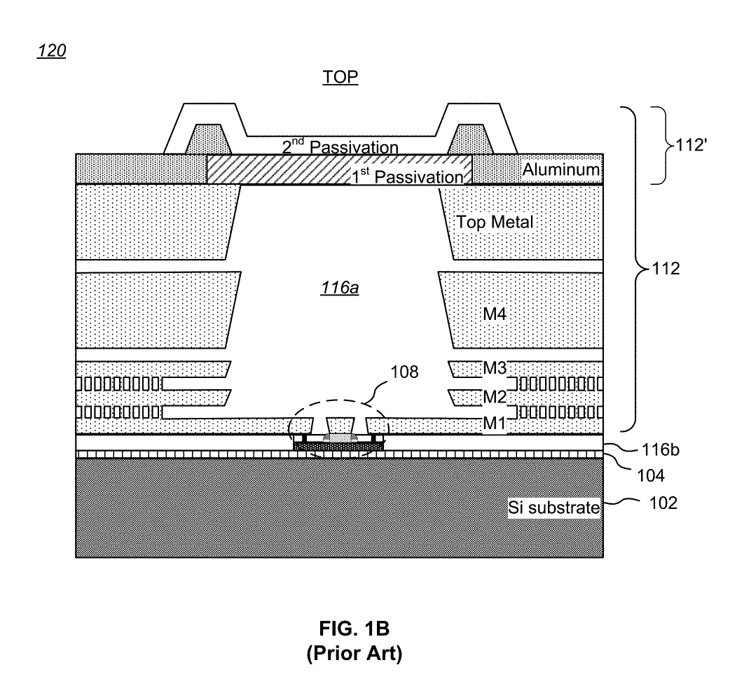

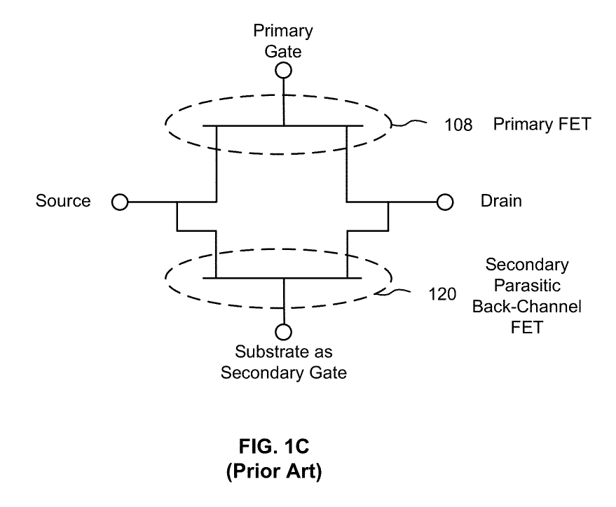

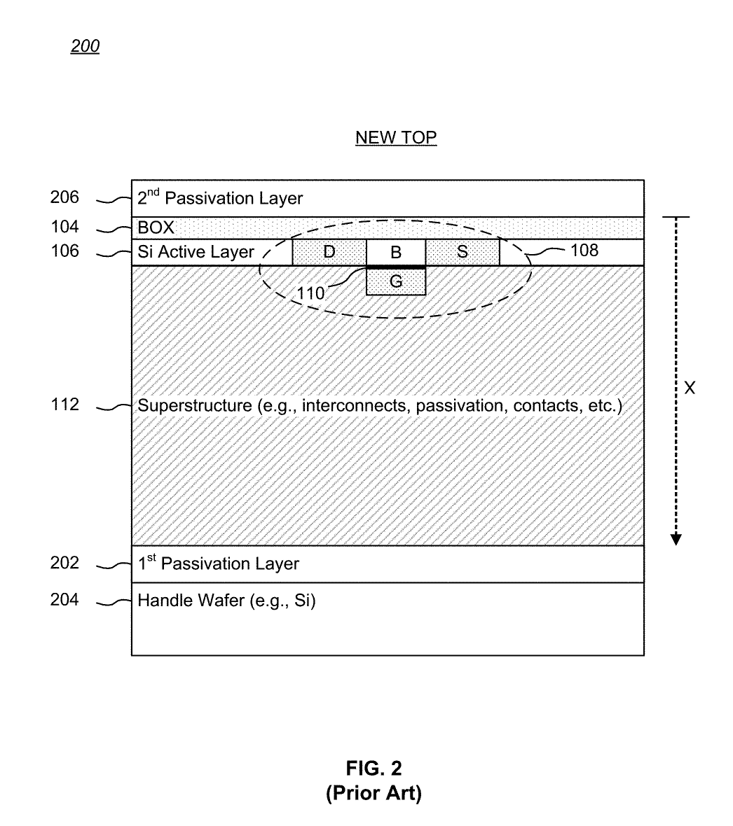

The IC structures 300, 310 are in part similar to the SLT wafer of FIG. 2, except that the second passivation layer 206 of FIG. 2 is modified by the creation of a specially aligned and patterned backside contact pattern (BCP) 302, which may be formed, for example, using redistribution layer (RDL) techniques. The BCP 302 is patterned to define the CAS gate, which is at least partially aligned with a corresponding primary FET 108 adjacent the (former) back-channel of the primary FET 108 and electrically isolated from the rest of the BCP 302. The BCP 302 (and thus the CAS gate) may be formed from aluminum or similar material in the same manner as conventional RDLs are formed on the top-side of the superstructure 112 of non-SLT wafers, such as is shown in FIG. 1B.

A CAS gate defined in the BCP 302 is spaced from the backside of the body B of the corresponding primary FET 108 by the BOX layer 104 and/or the second passivation layer 206 formed as part of the SLT process, as described in greater detail below. Accordingly, the BOX layer 104 and/or the second passivation layer 206 function as gate dielectric material for the CAS gate. The CAS gate, the gate dielectric material (i.e., BOX layer 104 and/or the second passivation layer 206) between the CAS gate and the body B of the primary FET 108, and the source S and drain D of the primary FET 108, forms a controllable MOSFET, with independent control provided by the CAS gate. This is in contrast with—and replaces—the formerly present but uncontrolled secondary parasitic back-channel FET 120 shown in FIG. 1A. The IC structures 300, 310 thus generally presents as a five-terminal device: source S, drain D, primary gate G, CAS gate, and a body contact (not shown). Note that there may be circumstances in which a CAS gate may be beneficial, but the body contact may not be needed, and thus such an IC structure would present as a four-terminal device. For example, some digital circuits such as memory cells may use a floating body (i.e., no body contact) for additional drive current, and a CAS gate for lower leakage current.

The relative thickness of the dielectric for the primary gate G is generally much thinner (typically on the order of 2 to 3 orders of magnitude thinner) than the dielectric for the CAS gate. Thus, the CAS gate generally will have a smaller impact on current and threshold voltage in the body B of the primary FET 108 for a particular applied voltage level. However, by applying control voltages to a CAS gate (typically DC voltages), various effects can be induced in and around the body B of the corresponding primary FET 108, depending on the type of transistor originally made in the SOI structure. For example, for a partially depleted SOI primary FET 108, the primary gate G and the CAS gate are isolated by undepleted silicon in the body B of the device. Hence, voltages applied to the CAS gate will mostly affect back-channel leakage current, meaning leakage current that cannot be controlled by the primary gate G. Such leakage currents can be large compared to the leakage currents of the body B under the primary gate G, often because the primary FET is designed to ensure low leakage currents. For digital systems, such leakage currents may be significant to overall system operation. For example, due to the large number of FETs in modern systems, small leakage currents can multiply into large wasted power consumption, especially for battery-operated portable devices. Even in the case of line-powered systems, wasted power and heat load can be substantially affected by leakage currents. Additionally, for RF and analog circuits, very low leakage is key to proper performance. Charged nodes or storage capacitors can be discharged by leakage currents, thereby forcing a recharge cycle that can induce spurious signals (“spurs”) in analog circuits that can degrade RF and analog system performance.

For a so-called fully depleted SOI primary FET 108, a voltage applied to the CAS gate will couple capacitively to the body B of the primary FET 108, thereby inducing some threshold voltage shift in the primary FET. The impact of leakage current in a fully depleted FET will have the same effects as for a partially depleted FET.

Another benefit of FETs having a CAS gate is that multiple FET devices can be identically fabricated (e.g., same implant doping levels) but controlled by respective CAS control voltages to operate with different threshold voltages, V_{T}. For example, in some applications, it may be useful to have some FETs with a lower V_{T} while other FETs have a higher V_{T}. This can be achieved by biasing the CAS gates of such FETs with different voltage values, which leads to the otherwise identical FETs exhibiting different threshold voltages V_{T}.

Important benefits of the invention include the following:

FETs that include a CAS gate have a higher voltage handling capability than conventional FETs (typically exceeding an added 1-2 VDC of voltage handling capability for an SOI NMOS FET with a CAS gate) due to the ability to bias the CAS gate such that the body B is more depleted than can be accomplished by the primary gate G alone; and

FETs that include a CAS gate have a lower ON resistance, R_{ON}, than conventional FETs (typically exceeding about 15% lower for switch FETs and about 30% lower for regular FETs, for SOI NMOS FETs with a CAS gate) due to the ability to bias the CAS gate such that the body B is more enhanced than can be accomplished by the primary gate G alone, resulting in lower insertion loss as well as a higher current capacity without increasing heat generation.

FETs that include a CAS gate may have lower leakage currents in subthreshold operating conditions due to the ability to bias the back-channel region of the body in a fully OFF condition.

Data from sample ICs embodying primary FETs with CAS gates show that the presence of a CAS gate does not change the current (Id) versus voltage (Vg) properties of the corresponding primary FET.

Notably, all of these benefits—particularly high voltage handling capability, low R_{ON}, and lower leakage currents—are available from the same FET under different operating conditions, just by varying the bias voltage applied to its CAS gate. These characteristics are particularly useful for signal switching applications, and especially RF signal switching circuits and systems.

Example Fabrication Steps

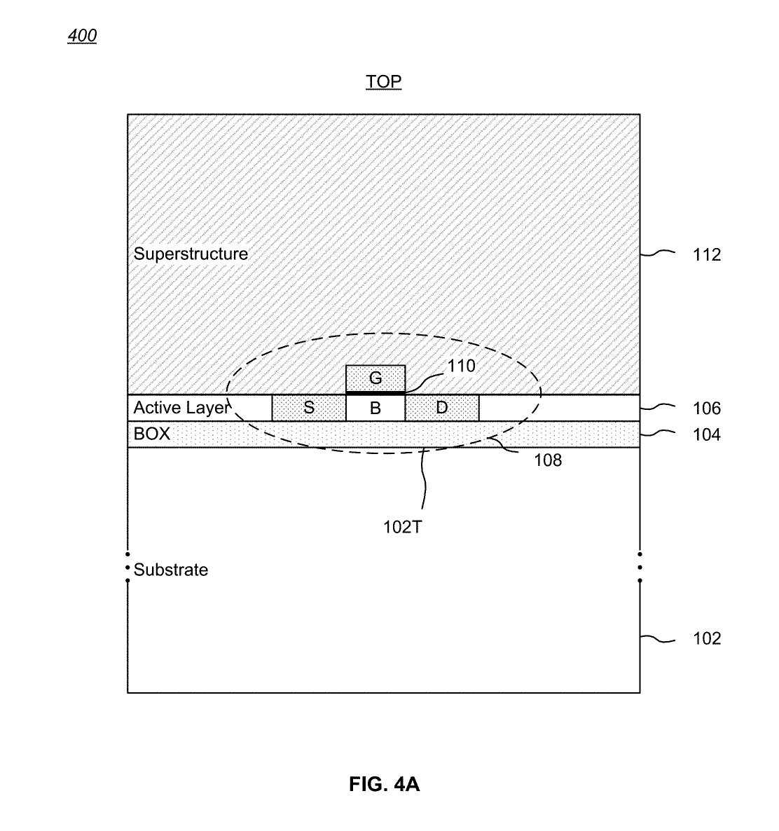

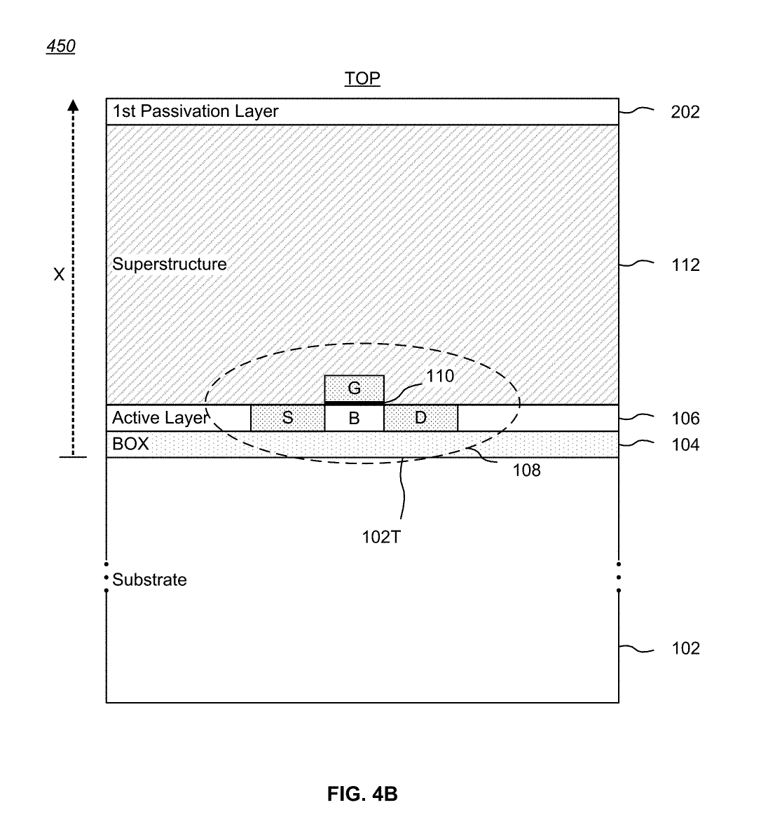

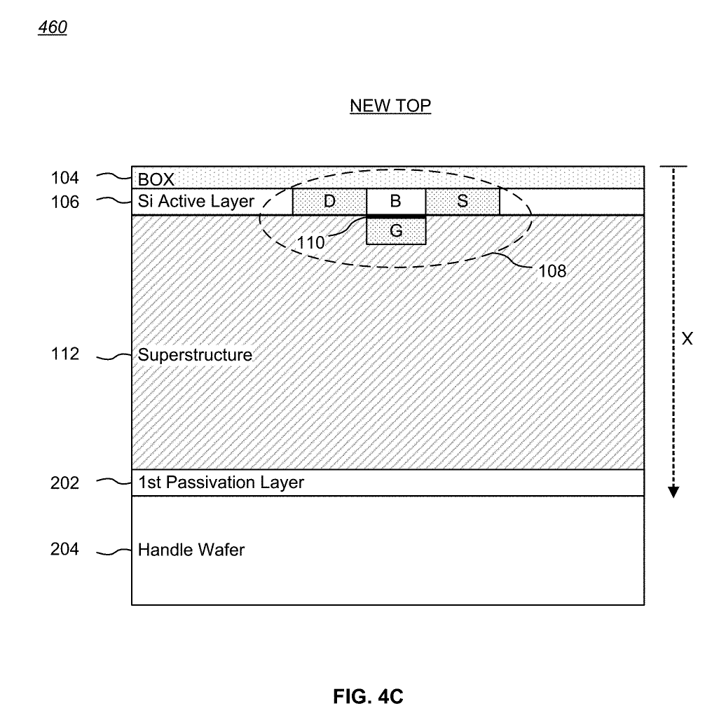

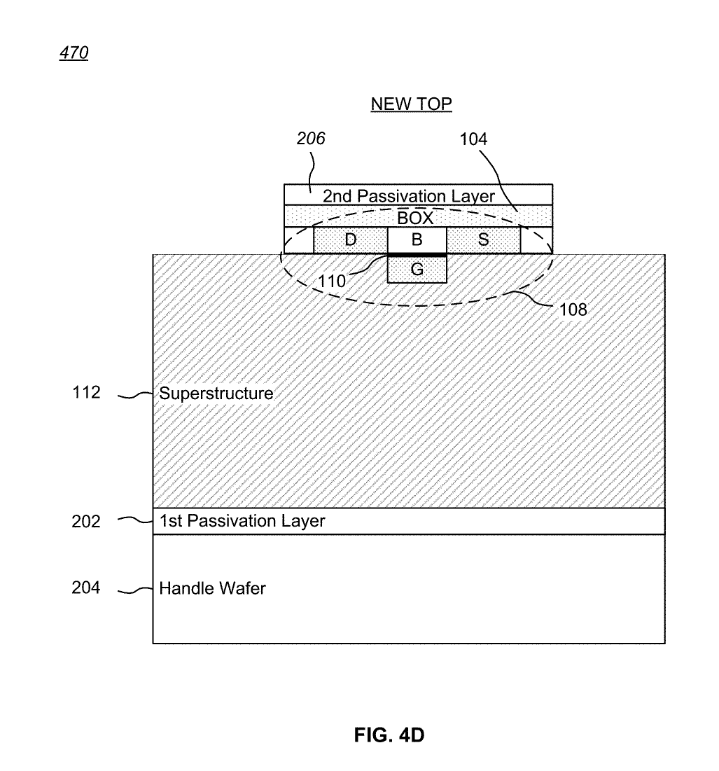

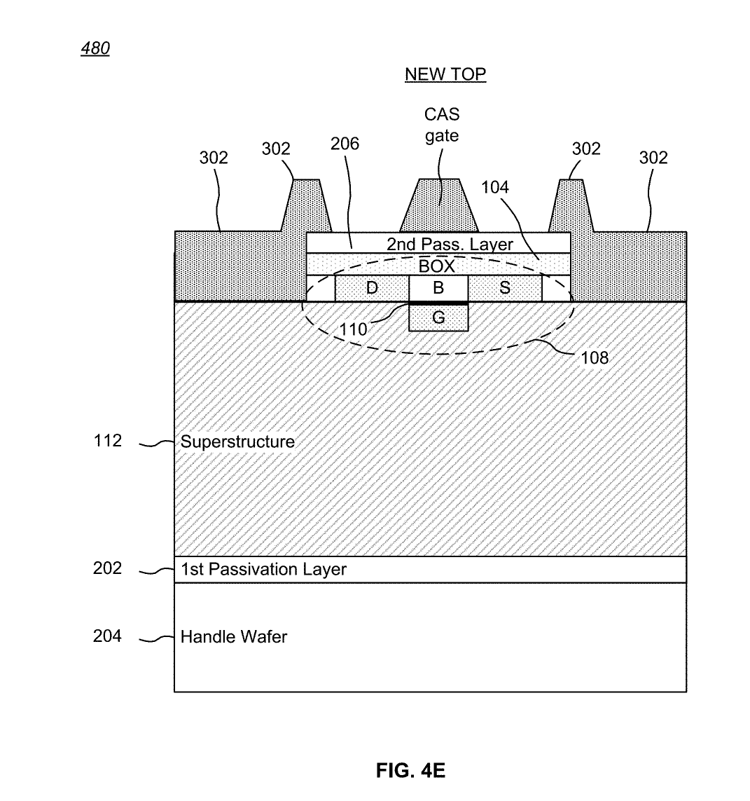

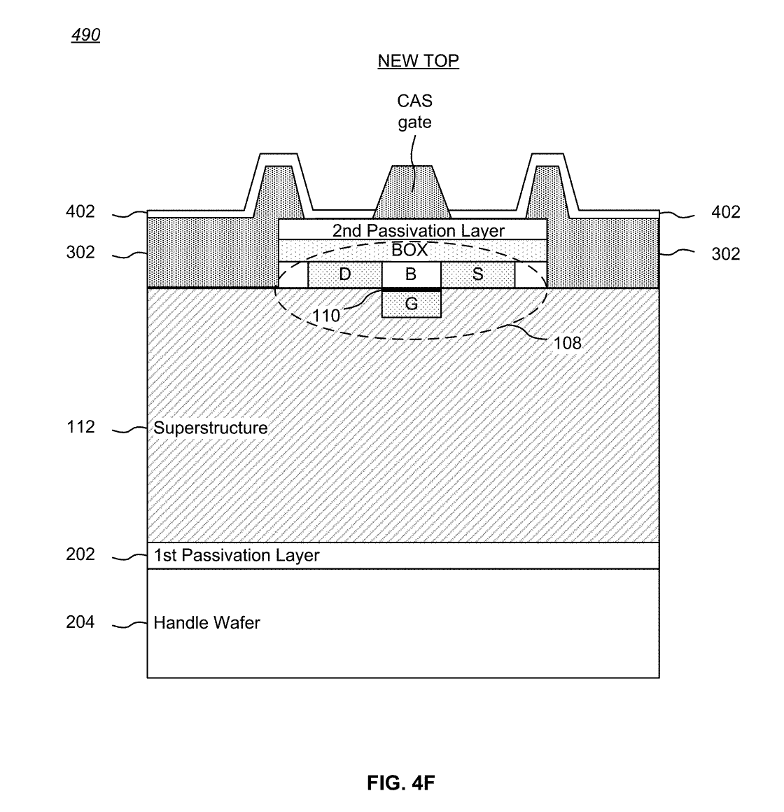

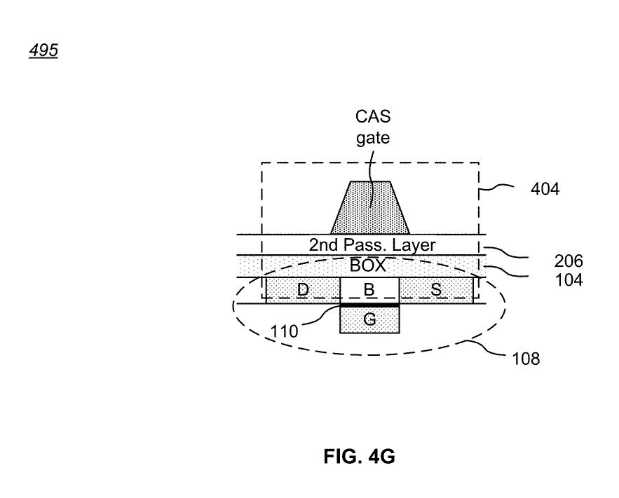

There are a number of ways in which the IC structures 300, 310 of FIGS. 3A and 3B may be fabricated. For an embodiment of the invention utilizing silicon-on-insulator (SOI) fabrication technology, the steps illustrated in FIGS. 4A-4F show one method of fabrication. However, it should be understood that the methods and devices structures described below may be readily adapted to other semiconductor-on-insulator fabrication technologies and devices structures.

FIG. 4A is a stylized cross-sectional view of a partial SOI IC structure 400 for a single primary FET 108, showing the results of a conventional fabrication process up to (but generally not including) application of a redistribution layer (RDL) on the top of the IC structure 400. Thus, the primary FET 108 has been formed within an active layer 106 formed on a BOX layer 104, which in turn has been formed on a substrate 102. Up to this point, the process is essentially the same as the process illustrated in FIG. 1A.

FIG. 4B is a stylized cross-sectional view of a partial SOI IC structure 450 comprising the partial SOI IC structure 400 of FIG. 4A and an added first passivation layer 202 formed on the exposed top surface of the superstructure 112. The first passivation layer 202 may be formed in known fashion, such as by deposition of insulating material (e.g., an oxide). The top surface of the first passivation layer 202 is preferably planarized by mechanical or chemical means to facilitate bonding to a handle wafer, in known fashion.

FIG. 4C is a stylized cross-sectional view of a partial SOI IC structure 460 comprising the partial SOI IC structure 450 of FIG. 4B after application of a backside access process, which in this particular example is a “single layer transfer” (SLT) process. As described above, the SLT process essentially flips an entire SOI transistor structure upside down onto a “handle wafer”, with the original substrate (e.g., substrate 102 in FIG. 4B) then being removed, thereby eliminating the substrate 102. Essentially, the original substrate 102 and the layers denoted as “X” in FIG. 4B are flipped over and bonded in known fashion to a handle wafer 204, as shown in FIG. 4C. The handle wafer 204 may be made of glass or other material that is transparent to at least one wavelength of light (including from infrared to x-rays) to facilitate one method of alignment for forming a CAS gate, as described in greater detail below. After bonding the flipped IC structure to the handle wafer 204, the original substrate 102 is removed in known fashion by mechanical and/or chemical means, exposing the BOX layer 104, which is now the “new top” of the IC structure 460.

FIG. 4D is a stylized cross-sectional view of a partial SOI IC structure 470 comprising the partial SOI IC structure 460 of FIG. 4C with added structures and modifications. More particularly, the new top of the IC structure 470 may be covered with a non-conductive second passivation layer 206 using conventional techniques. For example, the second passivation layer 206 may be a conventional interlayer dielectric (ILD) material. The second passivation layer 206 may be patterned to protect one or more selected primary FETs 108, and the new top of the IC structure 470 then etched down to the superstructure 112 surrounding the selected primary FETs 108, such that remaining portions of the second passivation layer 206 and of the BOX layer 104 define locations for those primary FETs. For example, the etching may remove material down to the M1 level of the superstructure 112.

FIG. 4E is a stylized cross-sectional view of a partial SOI IC structure 480 comprising the partial SOI IC structure 470 of FIG. 4D with added structures and modifications. More particularly, the new top of the IC structure 480 may be covered with a conductive material, such as aluminum or the like, and then patterned and etched, thus forming a backside contact pattern (BCP) 302. The BCP 302 may be formed, for example, using redistribution layer (RDL) techniques, except applied to the exposed “new top” of the IC structure 480. As noted above, the BCP 302 is specifically patterned to define a CAS gate at least partially aligned with a corresponding primary FET 108 and adjacent the (former) back-channel of the primary FET 108. In general, a CAS gate is aligned with the gate G of the primary FET 108. However, in some applications, it may be useful to off-set a CAS gate from substantial alignment with the gate G of the primary FET 108 to change the electrical properties of the device.

FIG. 4F is a stylized cross-sectional view of a partial SOI IC structure 490 comprising the partial SOI IC structure 480 of FIG. 4E with added structures and modifications. More particularly, the new top of the IC structure 490 may be patterned and covered in places with a deposited or formed protective or passivation layer 402, which may be, for example, ILD material. As shown in FIG. 4F, the CAS gate is not covered by the protective or passivation layer 402 so as to remain exposed in order to form or attach electrical connections.

FIG. 4G is a stylized cross-sectional detailed view of the primary FET 108 and CAS gate of FIG. 4F, omitting the other structures shown in FIG. 4F for clarity. The drain D, source S, the CAS gate dielectric material (i.e., BOX layer 104 and/or the passivation layer 206) between the CAS gate and the body B of the primary FET 108, and the CAS gate form a field effect transistor (shown in a dashed square 404). A primary FET 108 having an added CAS gate may be referred to as a “CAS-gated FET”.

As should be apparent to one of ordinary skill in the art, additional layers (not shown) may be formed and patterned on top of the protective or passivation layer 402 in order to connect CAS gates to control voltages and/or to form circuits between the CAS gates and other components.

In addition, the IC structure shown in FIG. 4F, including any added layers (including, for example, planarization layers) may be again “flipped” and bonded to a final substrate, after which the handle wafer 204 would be removed, thus leaving the superstructure 112 in a more accessible orientation for connection to external circuitry and/or IC packaging. This process is generally referred to as a “double layer transfer” (DLT).

Connections to the source S, drain D, and primary gate G are made in a conventional fashion, and interconnections between a plurality of primary FETs 108 may be made to suit a particular application. CAS-gated FETs may be fabricated as NMOS, PMOS, and/or CMOS transistor devices (comprising NMOS and PMOS devices), and such devices may be full or partial enhancement mode or full or partial depletion mode devices. As noted above, the threshold voltages V_{T} of the FETs can be varied as a function of the control voltage applied to their respective CAS gates.

As noted above, a single IC die may embody from one primary FET to millions of primary FETs. CAS gates may be fabricated for all or some of such primary FETs to form CAS-gated FETs. Thus, a single IC die may include both conventional primary FETs (i.e., without CAS gates) and one or more CAS-gated FETs. Mixing conventional primary FETs and CAS-gated FETs on an IC die may allow for better circuit control in some applications. Individual CAS gates may also be arranged to bias more than one primary FET.

CAS gates of a particular IC structure may be coupled to a common voltage, such as circuit ground or a non-zero potential. However, since CAS gates can be configured into circuits by adding additional layers on top of the protective or passivation layer 402, particular sets of CAS gate may be coupled to one or more different potentials, and the potentials may be actively controlled by suitable active layer switching and logic circuitry to meet the needs of particular applications.

In summary, one aspect of the invention encompasses a transistor device including a primary field effect transistor (FET) fabricated on a first side of an insulator layer, the primary FET including a source S, a drain D, a gate insulator, and a gate G; and a conductive aligned supplemental (CAS) gate, fabricated in relation to a second, opposite side of the insulator layer and aligned with at least a portion of the primary FET, such that the source S, the drain D, the CAS gate, and at least the insulator layer function as a field effect transistor. In another aspect, the source S, the drain D, and the gate G define a body B, and the gate G is configured to control electrical current flow in a first region within the body B while the CAS gate is configured to control electrical current flow in a second region within the body B. One of ordinary skill will understand that the first region and the second region within the same body may be overlapping (as in the example discussed above of a fully depleted FET).

Alignment

Embodiments of the invention include added steps to form a backside contact pattern (BCP) 302 having defined at least one conductive aligned supplemental (CAS) gate at least partially aligned with a corresponding primary FET 108 and adjacent the (former) back-channel of the primary FET 108. Accordingly, some care should be taken to align the BCP 302, particularly the CAS gates, to the buried structures and regions defining the primary FET 108. As noted above, in general, a CAS gate is aligned with the gate G of the primary FET 108. However, as also noted above, in some applications, it may be useful to off-set a CAS gate from substantial alignment with the gate G of the primary FET 108 to change the electrical properties of the device.

One method for facilitating the task of alignment is making the handle wafer 204 in FIGS. 4C-4F transparent to at least one wavelength of light (including from infrared to x-rays), and forming fiducial marks in or on the superstructure 112 that define the location of a primary FET 108. For example, the handle wafer 204 may be made of glass, which is substantially transparent to at least visible light, or of thin silicon, which is substantially transparent to infrared light. The fiducial marks can then be imaged through the handle wafer 204 using conventional IC fabrication equipment in order to align the masks used for forming the BCP 302, including CAS gates.

Performance Characteristics

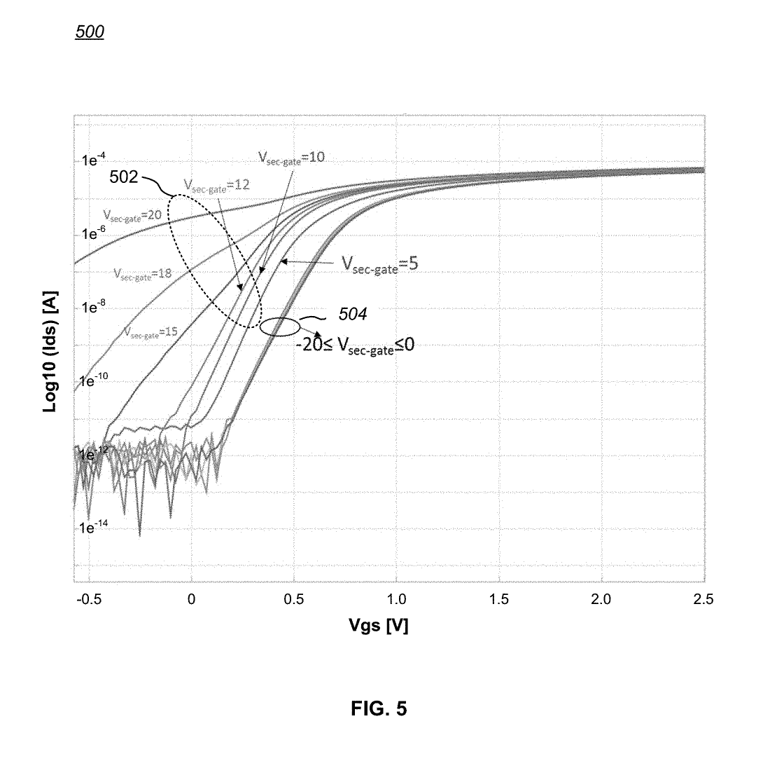

FIG. 5 is a graph of drain-source current (on a log10 scale) of a CAS-gated FET as a function of primary gate-source voltage, for different values of CAS secondary gate control voltages. The set of graph curves encircled by dotted oval 502 are for positive CAS secondary gate control voltages (“Vsec-gate” values) from 5V to 20V, and show that the leakage current of the FET can be changed as a function of such positive CAS secondary gate control voltages. Conversely, the set of graph curves encircled by solid oval 504 are for non-positive CAS secondary gate control voltages from 0V to −20V, and show that the leakage currents of the FET is fully controlled by such CAS secondary gate control voltages. The effect of negative CAS voltages saturates because once the back-channel is fully turned OFF, it no longer contributes what had been uncontrolled back-channel leakage currents.

Methods

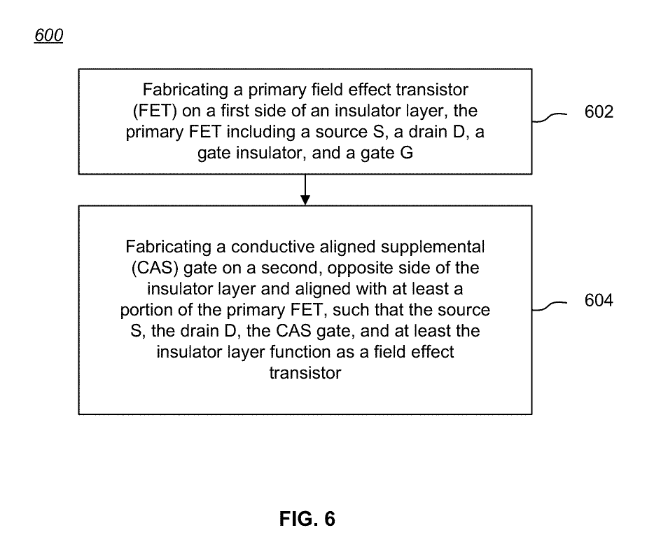

Another aspect of the invention includes methods for making a transistor device, including transistor devices having a CAS gate structure. For example, FIG. 6 is a process flow diagram of a first method 600 for making a transistor device. In this example, the method 600 includes: fabricating a primary field effect transistor (FET) on a first side of an insulator layer, the primary FET including a source S, a drain D, a gate insulator, and a gate G (STEP 602); and fabricating a conductive aligned supplemental (CAS) gate on a second, opposite side of the insulator layer and aligned with at least a portion of the primary FET, such that the source S, the drain D, the CAS gate, and at least the insulator layer function as a field effect transistor (STEP 604).

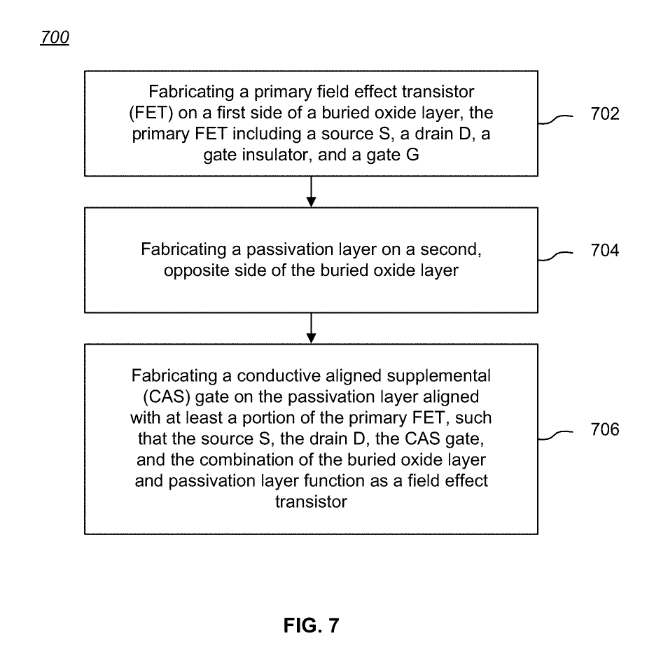

As another example, FIG. 7 is a process flow diagram of a second method 700 for making a transistor device. In this example, the method 700 includes: fabricating a primary field effect transistor (FET) on a first side of a buried oxide layer, the primary FET including a source S, a drain D, a gate insulator, and a gate G (STEP 702); fabricating a passivation layer on a second, opposite side of the buried oxide layer (STEP 704); and fabricating a conductive aligned supplemental (CAS) gate on the passivation layer aligned with at least a portion of the primary FET, such that the source S, the drain D, the CAS gate, and the combination of the buried oxide layer and passivation layer function as a field effect transistor (STEP 706).

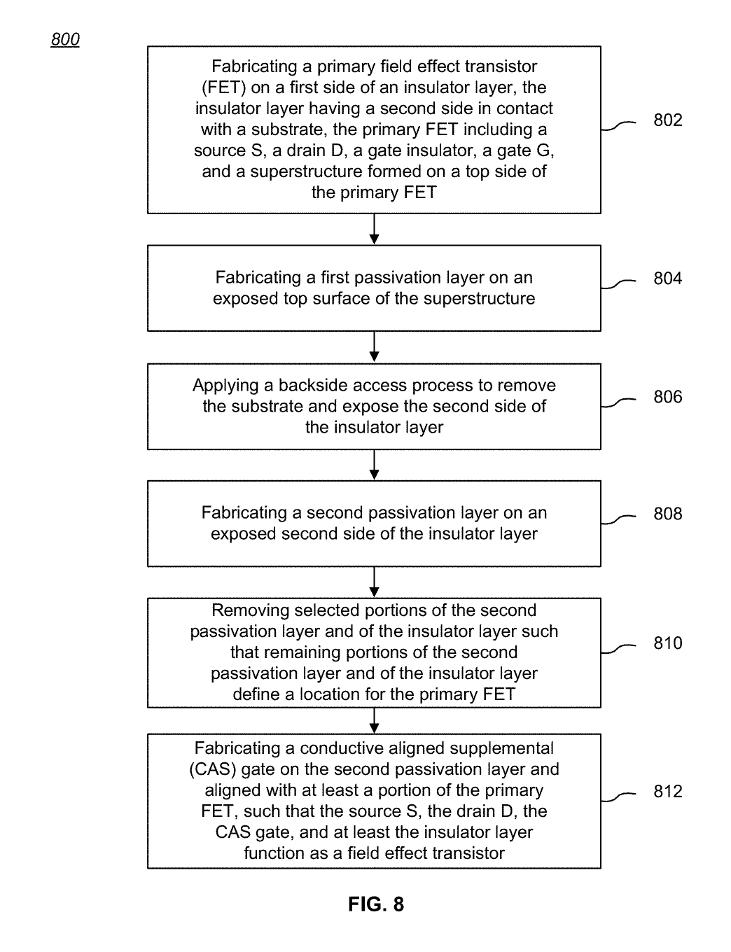

As yet another example, FIG. 8 is a process flow diagram of a third method 800 for making a transistor device. In this example, the method 800 includes: fabricating a primary field effect transistor (FET) on a first side of an insulator layer, the insulator layer having a second side in contact with a substrate, the primary FET including a source S, a drain D, a gate insulator, a gate G, and a superstructure formed on a top side of the primary FET (STEP 802); fabricating a first passivation layer on an exposed top surface of the superstructure (STEP 804); applying a backside access process to remove the substrate and expose the second side of the insulator layer (STEP 806); fabricating a second passivation layer on an exposed second side of the insulator layer (STEP 808); removing selected portions of the second passivation layer and of the insulator layer such that remaining portions of the second passivation layer and of the insulator layer define a location for the primary FET (STEP 810); and fabricating a conductive aligned supplemental (CAS) gate on the second passivation layer and aligned with at least a portion of the primary FET, such that the source S, the drain D, the CAS gate, and at least the insulator layer function as a field effect transistor (STEP 812).

Other aspects of the above methods may include one or more of the following: fabricating the transistor device as an integrated circuit using a semiconductor-on-insulator process; fabricating the transistor device with one of a silicon-on-insulator process or a silicon-on-sapphire process; fabricating a passivation layer interposed between the CAS gate and the insulator layer; wherein the source S, the drain D, and the gate G define a body B, and wherein the gate G is configured to control electrical current flow in a first region within the body B, and the CAS gate is configured to control electrical current flow in a second region within the body B; biasing the CAS gate with a first voltage to lower an ON resistance, R_{ON}, of the transistor device; biasing the CAS gate with a second voltage to increase a voltage handling capability of the transistor device; and/or biasing the CAS gate in a first mode of operation with a first voltage to lower an ON resistance, R_{ON}, of the transistor device, and in a second mode of operation with a second voltage to increase a voltage handling capability of the transistor device.

Still other aspects of the above methods may include one or more of the following: wherein the source S, the drain D, and the gate G define a body B, wherein the gate G is configured to control electrical current flow in a first region within the body B, and the CAS gate is configured to control electrical current flow in a second region within the body B; biasing the CAS gate with a first voltage to lower an ON resistance, R_{ON}, of the transistor device; biasing the CAS gate with a second voltage to increase a voltage handling capability of the transistor device; biasing the CAS gate in a first mode of operation with a first voltage to lower an ON resistance, R_{ON}, of the transistor device, and in a second mode of operation with a second voltage to increase a voltage handling capability of the transistor device; and/or wherein fabricating a CAS gate on the second passivation layer includes forming a conductive layer over the second passivation layer, patterning the conductive layer to define at least the CAS gate, and removing at least a portion of the conductive layer to form the defined CAS gate.

Fine Conductive Line CAS Gates

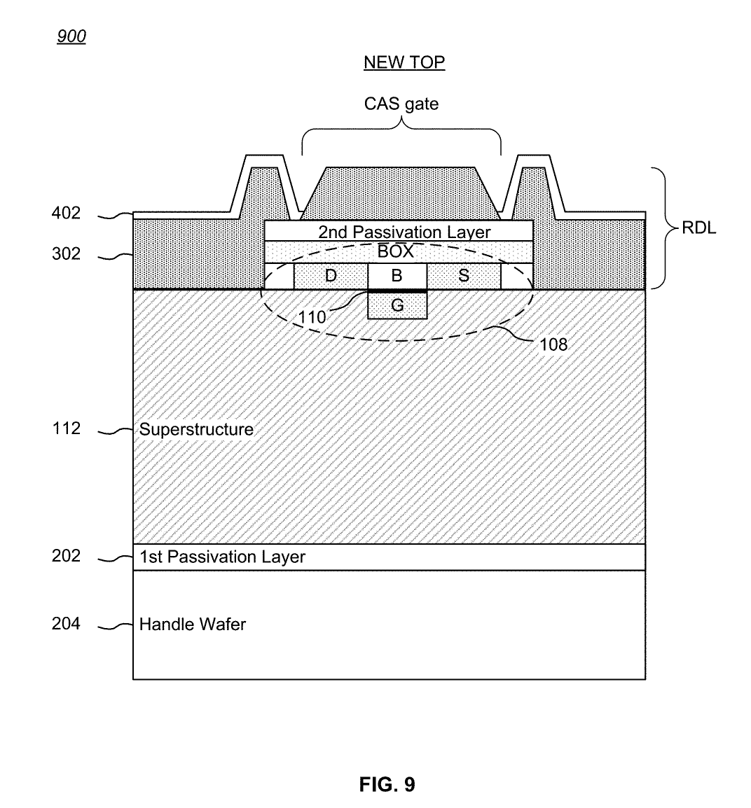

As noted above, CAS gates may be fabricated from a redistribution layer (RDL), typically comprising aluminum or copper. However, an RDL is fabricated on wafers after the wafers have left a front-end fabrication process, and in many IC fabrication foundries or factories, RDL's are typically thick layers with relatively coarse features and relatively poor alignment to the underlying FET structures. For example, FIG. 9 is a stylized cross-sectional view of a CAS-gated FET having a relatively coarse CAS gate formed in a patterned backside contact pattern (BCP) 302 of an RDL layer. Ideally, a CAS gate should span only about the body B region in FIG. 9. However, in the example illustrated in FIG. 9, the CAS gate spans most or all of the drain D and source S regions (and in some processes, may more than span the drain D and source S regions, and may even span across multiple FETs). Such relatively coarse CAS gate structures may have several negative side effects, including the following: (1) increased transistor OFF capacitance, CUFF, due to increased source/drain capacitance with respect to the CAS gate (in some modeled examples, C_{OFF} increased by more than 10%, which is significant in RF applications); (2) increased drain capacitance, thereby reducing the voltage division capability of a stack of FETs and requiring additional capacitive compensation; (3) extending CAS gate effects to nearby regions that may not need or benefit from a CAS gate; and/or (4) consumption of IC area that may block creation of other structures and/or connections.

Some IC front-end fabricators provide the ability to fabricate a backside conductive layer (BCL) on the “new top” of FET IC structure after performing a backside access process, such as an SLT or DLT process, and before or in lieu of an RDL process. A BCL or BCL region may be patterned to form fine conductive lines (FCLs). A BCL (and thus FCLs) may comprise a metal, such as copper or aluminum, or may a generally conductive material, such as polysilicon or conductive polymers. Within the same fabrication process, FCLs may have a line width that is only about 25% or less of the line width available at the RDL level. For example, in one process, FCLs can have lines and spaces as fine as about 0.5 μm, while RDL lines in the same process can only have lines as fine as about 2-3 μm, and spaces may be even greater.

FCLs may be advantageously used to form more precisely sized and aligned CAS gates, especially in comparison to many RDL processes, such that little or none of an FCL CAS gate overlaps (i.e., is vertically aligned with and in spaced relation) a corresponding FET source S or drain D. In some embodiments, bias voltages may be applied to FCL CAS gates by making contact with the FCLs from the “new top” of a post-SLT processed IC structure. However, a version of conductive substrate contact (S-contacts)—perhaps better styled as “through BOX contacts” or TBC's in this context—may be fabricated before performing a backside access process to create electrical connections between FCLs and the metal layers of the superstructure 112 of an IC, thereby enabling significantly increased functionality. For example, TBC's facilitate the ability to individually bias individual FCL CAS-gated FETs or groups of FCL CAS-gated FETs, and to couple integrated components to the FCLs, such as resistors, capacitors, and/or inductors fabricated within the superstructure 112.

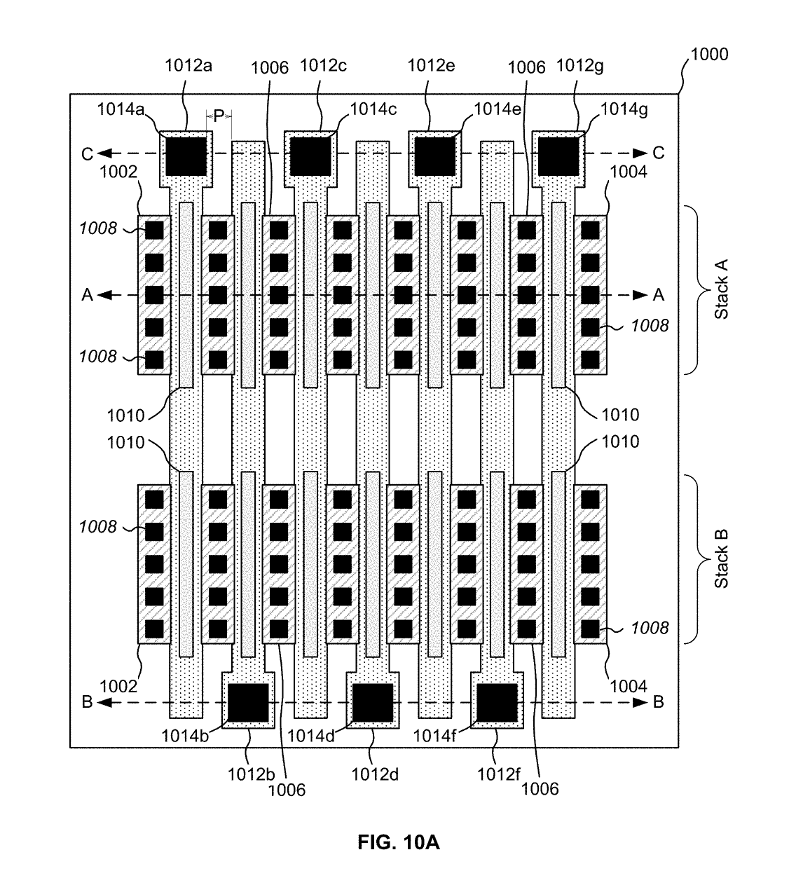

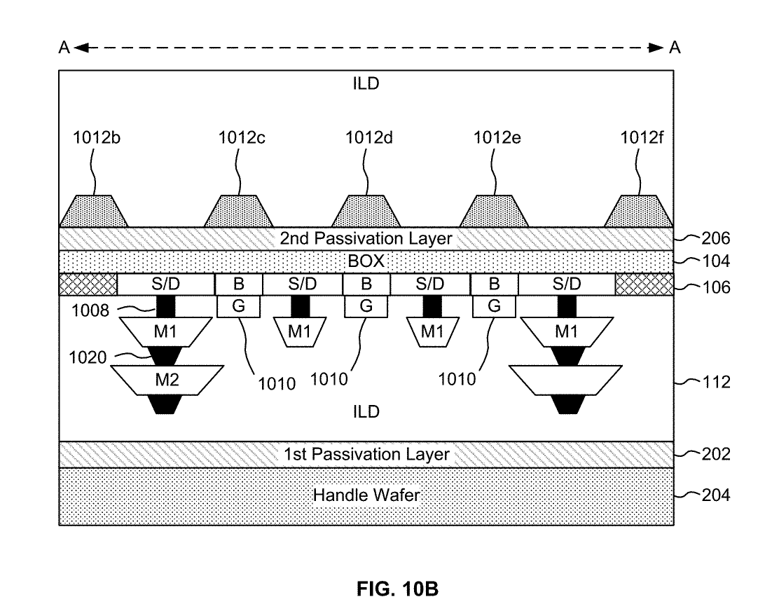

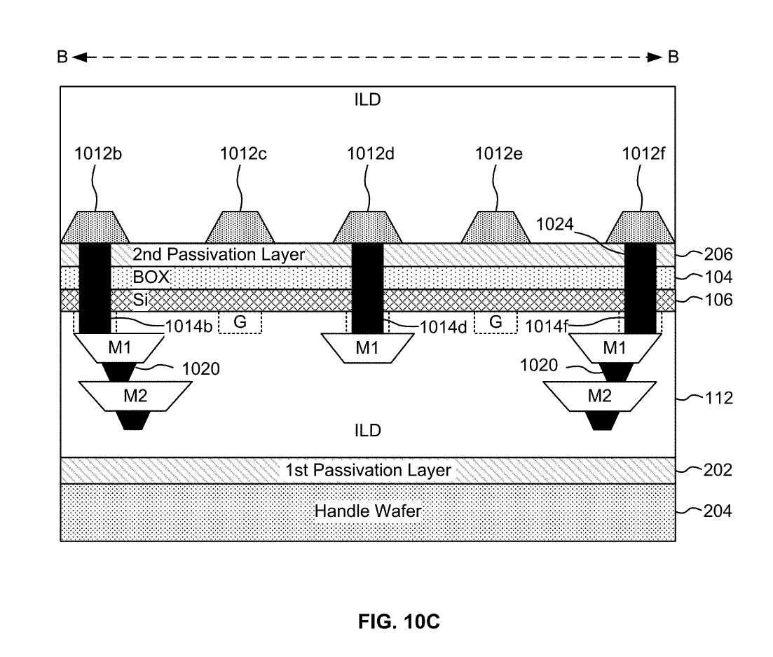

As one example, FIG. 10A shows a top view of an IC structure 1000 that includes two 7-FET stacks of CAS-gated FETs formed with fine conductive lines. FIG. 10B is a cross-sectional view of the IC structure 1000 taken along line A-A for the innermost five of the FETs of FIG. 10A. FIG. 10C is a cross-sectional view of the IC structure 1000 taken along line B-B for the innermost five of the FETs of FIG. 10A.

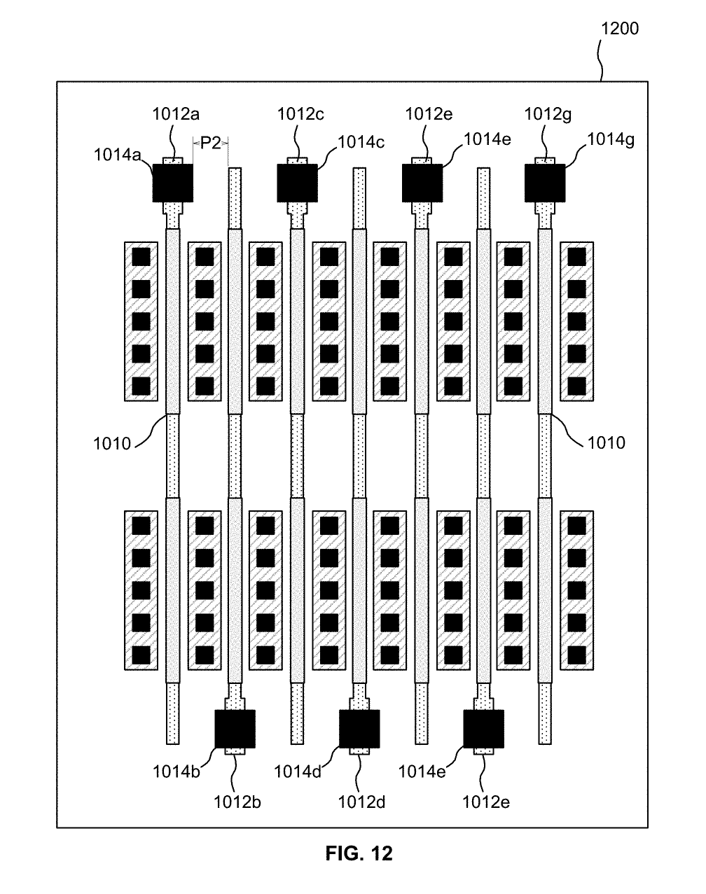

FIG. 10A shows FET stacks A and B each comprising seven adjacent and parallel FETs series-connected source-to-drain (note that the handle wafer 204, first passivation layer 202, and most of the superstructure 112 of FIGS. 10B and 10C are omitted for clarity). In each stack, one end FET has a source 1002 and an opposing end FET has a drain 1004. For area savings and performance improvement, the source and drain regions of intermediate adjacent FETs are merged, as a source/drain 1006. Of course, more or fewer (down to one) FET may be used, depending on the application. The sources 1002, drains 1004, and merged sources/drains 1006 each have multiple electrical vias 1008 to provide signal connection to the conductive interconnect levels 112 of FIG. 12B, generally to the M1 level. The sources and drains of each FET define a body B (see FIG. 10B) overlaid by a primary gate 1010 (underlying gate insulator and contacts to the gates 1010 are omitted for clarity). In the illustrated example, aligned with each primary gate 1010 is a corresponding CAS gate 1012a-1012g formed on the opposite side of the BOX layer 104 using FCLs. In this example, each FCL CAS gate 1012a-1012g is associated with a dedicated TBC 1014a-1014g. In the illustrated example, the paired gates 1010 and FCL CAS gates 1012x are arrayed in parallel. (To avoid clutter, not all of the instances of all elements are labeled).

The two FET stacks A, B may be used, for example, in an RF switch or amplifier. Each FET stack A, B is independent, but since each primary gate 1010 in one FET stack is aligned with a corresponding primary gate 1010 in the other FET stack, those aligned primary gates 1010 can share a common FCL CAS gate. The illustrated FET stacks A, B may also be connected in parallel by metal interconnects (but not in series, since the primary gates with a common FCL gate would then see different RF potentials).

Cross-section FIG. 10B shows just the five innermost FETs with merged sources/drains S/D (the end FETs are omitted for the sake of space). The structure is similar to the structure shown in FIG. 4D (before etching in preparation for the structure of FIG. 4E), except that FCL CAS gates 1012x have been added. The FCLs may be formed by well-known fabrication techniques. For example, the FCLs may be formed with a subtractive process, in which a conductive layer is formed over the second passivation layer 206, and then the conductive layer is masked and etched to form fine lines. As another example, the FCLs may be formed with an additive process, in which an insulating layer (which may be the second passivation layer 206 itself) is masked and etched to form voids where the fine lines are to be located, and then the voids filled with a conductor (e.g., copper). In either case, an insulating later (e.g., ILD) may be formed over the FCLs for environmental protection and electrical insulation. In alternative embodiments, the FCLs may be formed directly on the BOX layer 104, starting with a partially completed structure similar to the structure shown in FIG. 4C.

During a backside access process, such as an SLT or DLT process, when the backside of an IC structure is exposed on which a BCL and/or FCLs may be formed, alignment of masks for forming the BCL and/or FCLs may be accomplished by imaging fiducial marks previously formed on the front side of the IC structure (e.g., in the active layer 106 or a conductive interconnect levels—generally the M1 level, as closest), since the second passivation layer 206, the BOX layer 104, and the active layer 106 are generally very thin and often essentially transparent to at least one wavelength of light (including from infrared to x-rays).

In the example shown in FIG. 10B, the superstructure 112 includes two conductive interconnect levels M1, M2 patterned to connect to the merged sources/drains S/D (directly or indirectly, through other conductive interconnect levels) by vias 1008, 1020. Other patterned conductive interconnect levels M3-Mx may be included as needed for IC region and circuit interconnections.

FIG. 10C also shows just the five innermost FETs with merged sources/drains S/D (not visible in this cross-section, but note that some of the gates G are shown in dotted outline to provide orientation with respect to FIG. 10B). In this view, it can be seen that three FCL CAS gates 1012b, 1012d, 1012f are coupled by corresponding TBC's 1014b, 1014d, 1014f to the M1 conductive interconnect level in the superstructure 112. While not shown, a cross-sectional view along line C-C of FIG. 10A would similarly show that four FCL CAS gates 1012a, 1012c, 1012e, 1012g are coupled by corresponding TBC's 1014a, 1014c, 1014e, 1014g to the M1 conductive interconnect level in the superstructure 112.

As described above and in U.S. Pat. No. 9,837,412 referenced above, S-contacts are formed from the superstructure 112 so as to penetrate through the active layer 106 to the BOX layer 104 or to conductive regions or wells formed in and/or above the BOX layer 104. S-contacts may also be formed so as to penetrate completely through the BOX layer 104 to the initial substrate 102, which would be useful for contacting BCL regions and FCLs. However, while formed in the same manner as S-contacts of the type described in U.S. Pat. No. 9,837,412, since the initial substrate 102 is removed during a backside access process, it is more appropriate to refer instead to “through BOX contacts” or TBC's.

Since FCL CAS-gated FETs are formed as part of the same backside access process used for fabricating the IC structure 1000 (e.g., within a CMOS fabrication facility), the FCLs can have finer lines, better alignment, and potentially more complex structures than an RDL-based process for making CAS gates. Referring again to FIGS. 10A-10C, FCL CAS gates 1012x can be sized to be similar in width and length to the primary gates 1010. In preferred embodiments, a FCL CAS gate 1012x is aligned in both the X dimension (i.e., across FIGS. 10A-10C) and the Y dimension (i.e., vertically in FIG. 10A, and into the page for FIGS. 10B and 10C) such that at least half of the FCL CAS gate 1012x is vertically aligned (i.e., through the BOX layer 104) with the corresponding primary gate 1010, and such that little or none of the corresponding FET source S or drain D (whether or not a merged source/drain) is vertically aligned to the FCL CAS gate 1012x.

Misalignment Mitigation

While alignment of backside masks for purposes of forming BCL regions and FCLs can be done reasonably precisely in most fabrication processes capable of fabricating BCL regions and FCLs, in some fabrication processes, misalignment of BCL regions and FCLs with respect to TBC's may pose an issue. However, there are several techniques that may be used to mitigate such misalignment issues.

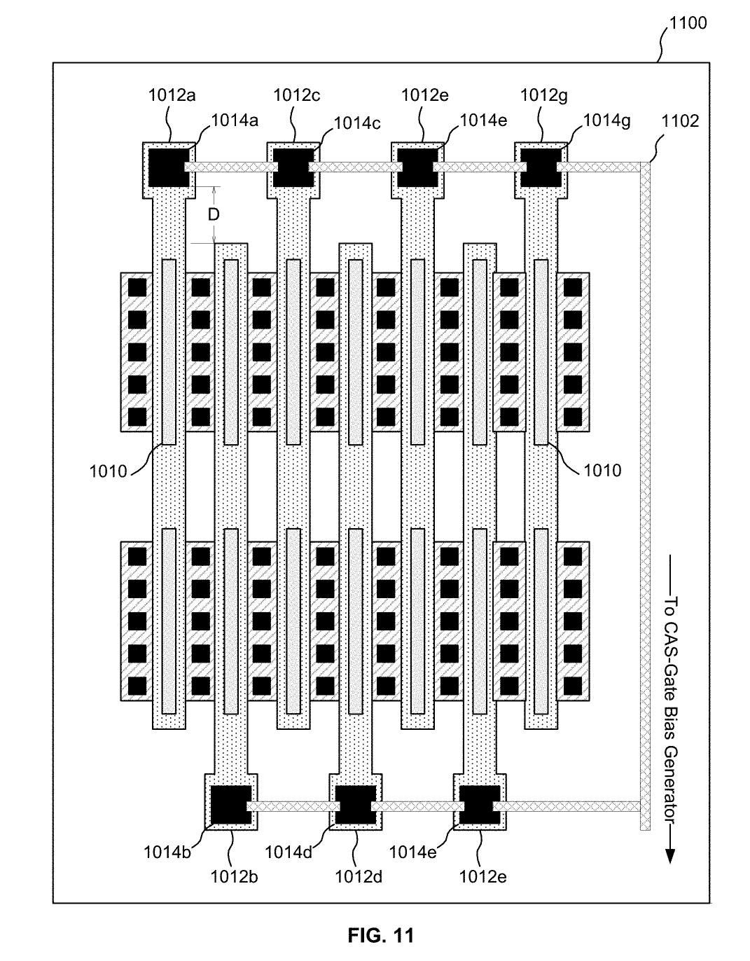

For example, FIG. 11 shows a top view of an IC structure 1100 that illustrates a first type of misalignment mitigation structure for FCL CAS-gated FETs with respect to TBC's. While similar to the IC structure 1000 of FIG. 10A (but omitting some reference numbers to avoid clutter), the interdigitated FCL CAS-gates are offset along their length with respect to the TBC's of adjacent FCLs. In FIG. 10A, for example, the unconnected ends of the FCL CAS-gates 1012a-1012g are within a lateral distance “P” of adjacent TBC's 1014a-1014g. Some amount of misalignment—such as horizontal or vertical displacement (with respect to the figure image) or even rotational skew—of the masks for forming the FCL CAS-gates may cause unconnected ends of the FCL CAS-gates to overlap with the adjacent TBC's. However, by offsetting the unconnected ends of the FCL CAS-gates 1012a-1012g from the TBC's of adjacent FCLs by a distance D, as shown in FIG. 11, a sufficiently small degree of misalignment cannot bring the unconnected ends of the FCL CAS-gates 1012a-1012g into contact with the adjacent TBC's, and only one FCL CAS-gate 1012x should contact a corresponding TBCx. Note that even partial contact of CAS-gate FCLs to correct corresponding TBC's should be sufficient to provide a desired potential with respect to the body B of the corresponding FET. While such misalignment of the FCL CAS-gates 1012a-1012g will also cause some misalignment with respect to overlying primary gates 1010 and corresponding FET bodies (not shown), sufficient overlap should exist to effectively manage body current. Accordingly, the distance D essentially sets a tolerance level for misalignment.

FIG. 11 also illustrates an optional feature, which is to provide a common CAS-gate bias voltage to multiple backside FCL CAS-gates 1012a-1012g through front side connectors 1102 that connect all of the TBC's 1014a-1014g to a CAS-gate bias generator (not shown). In some embodiments, the front side connectors 1102 may be fabricated with a material having a suitable resistance (e.g., polysilicon) to essentially form a resistor between mutually-connected TBC's, thus providing high impedance paths for AC signals. The relatively high impedance of the front side connectors 1102 between TBC's thus forms a resistive CAS-gate bias ladder.

It should also be noted that TBC's themselves may have an appreciable resistance. For example, in some fabrication processes, TBC's may each have a resistance of about 2 ohms. Accordingly, such resistive TBC's may be connected in series through front side conductive connections (e.g., through the conductive interconnect levels M1-Mx) and backside BCL regions and FCLs to create resistors of larger value. For example, 25 TBC's connected in series would create about a 50 ohm load, using only the area of the TBC's combined areal cross-section. Alternatively, TBC's could be connected in parallel, creating very low resistance contacts, potentially as distributed ground contacts throughout an RF substrate.

FIG. 12 shows a top view of an IC structure 1200 that illustrates a second type of misalignment mitigation structure for FCL CAS-gated FETs with respect to TBC's. In the illustrated embodiment, the width of the interdigitated FCL CAS-gates 1012a-1012g is made smaller than the width of the TBC's 1014a-1014g such that each FCL CAS-gate 1012x is in electrical contact with at least some part of the corresponding TBCx and is not in electrical contact with any adjacent TBC. For example, while the unconnected ends of the FCL CAS-gates 1012a-1012g in FIG. 10A are within a distance “P” of adjacent TBC's 1014a-1014g, by reducing the width of the FCL CAS-gates 1012a-1012g to less than the width of the TBCs, the corresponding distance in FIG. 12 is increased to “P2”. A similar result can be achieved by reducing the dimensions of the TBCs, although process limitations may require a minimum TBC size.

As should be appreciated, the misalignment mitigation structures of FIGS. 11 and 12 can be combined for increased misalignment tolerance.

The interdigitated “finger” structure of the FCL CAS-gates 1012a-1012g in FIGS. 10A, 11, and 12 allows each FCL CAS-gate to be individually biased through corresponding dedicated TBC's 1014a-1014g. As noted above, a benefit of FETs having CAS gates is that multiple FET devices can be identically fabricated (e.g., same implant doping levels) but controlled by respective CAS control voltages to operate with different threshold voltages, V_{T}. For example, in some applications, it may be useful to have some FETs with a lower V_{T} while other FETs have a higher V_{T}. This can be achieved by biasing the FCL CAS-gates 1012a-1012g with different voltage values, which leads to otherwise essentially identical FETs exhibiting different threshold voltages V_{T}. Similarly, groups of FETs may be commonly biased through the combination of FCL CAS-gates and front side commonly-connected TBC's to allow different threshold voltages V_{T} per group. In any case, the ability to independently bias the CAS gate of one or more FETs in a FET stack enables adjustable voltage division of the FET stack.

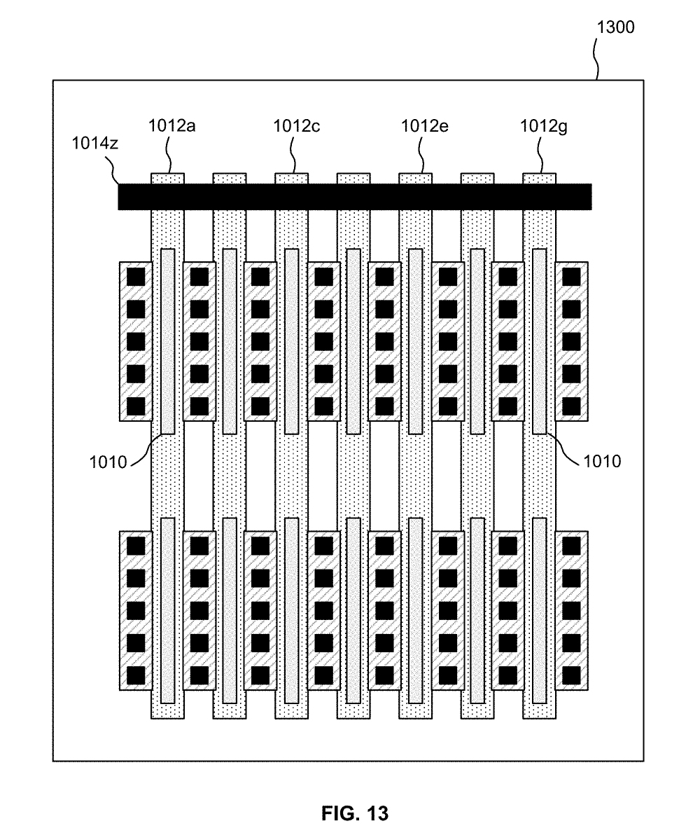

FIG. 13 shows a top view of an IC structure 1300 that illustrates a third type of misalignment mitigation structure for FCL CAS-gated FETs with respect to TBC's. In the illustrated embodiment, rather than forming TBC's on alternating sides of an IC structure, as in FIGS. 10B-10C, 11, and 12, one end of each of the parallel FCL CAS-gates 1012a-1012g is formed in electrical contact with a single “busbar” TBC 1014z formed through the BOX layer 104, thereby substantially mitigating the problem of misalignment horizontally and vertically (with respect to FIG. 13). For example, busbar TBC's can allow for relatively large horizontal misalignment—at least about 1-2 μm with current RF CMOS IC fabrication processes—in the FCL CAS-gate pattern and yet remain sufficiently effective to achieve biasing control of the body B. Another advantage of busbar TBC's is that there is no interfinger capacitance, since as all the FCL CAS-gates 1012a-1012g are at the same DC/AC potential.

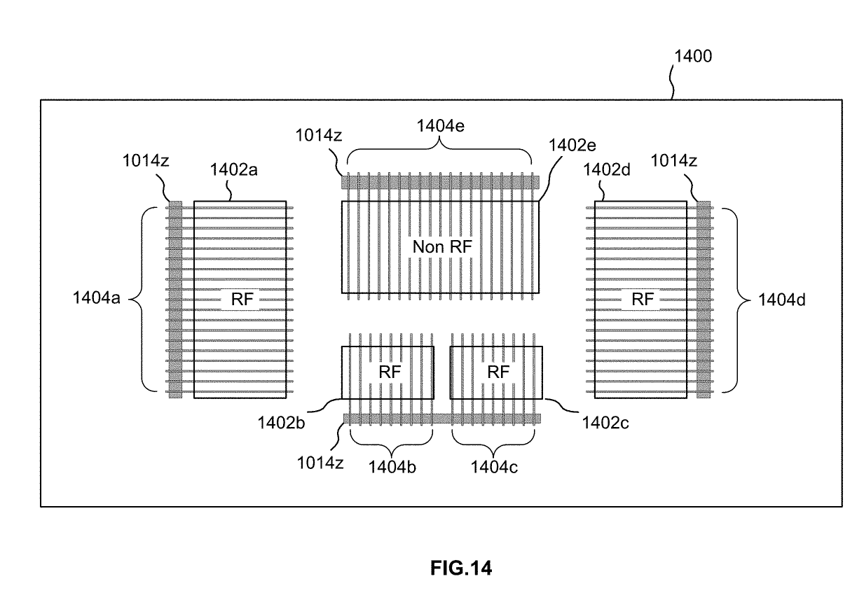

A particular IC need not have the same CAS-gate bias applied to all portions of the IC circuitry, and the FCL CAS-gates need not all have the same orientation. For example, FIG. 14 is a top view of a stylized integrated circuit 1400 having distinct sub-circuit regions 1402a-1402e.

In the illustrated example, sub-circuit regions 1402a-1402d comprise RF circuitry, while sub-circuit region 1402e comprises non-RF circuitry. Each of the sub-circuit regions 1402a-1402e has a corresponding set of FCL CAS-gates 1404a-1404e connected to a busbar TBC 1014z, with the FCL CAS-gates 1404b and 1404c for sub-circuit regions 1402b and 1402c being commonly biased by the same busbar TBC 1014z (of course, some of the circuitry need not utilize CAS-gated FETs). As an example, the FCL CAS-gates 1404a for sub-circuit region 1402a may be biased at a first level to achieve a desired R_{ON} or BVDss characteristic, while the FCL CAS-gates 1404e for sub-circuit region 1402e may be biased at a second level to achieve a different desired R_{ON} or BVDss characteristic. As illustrated, one or more of the busbar-connected FCL CAS-gates 1404a-1404e may be oriented differently with respect to the other busbar-connected FCL CAS-gates 1404a-1404e. Note also that while FIG. 14 and the other figures show FCL CAS-gates having arrays of straight parallel fingers, other patterns (e.g., non-straight but parallel fingers) may be used as called for by particular applications.

An additional advantage of the circuitry layout shown in FIG. 14 is that the FCLs patterns can be used to shield circuits, which in some applications allows placement of IC connection pads directly over such circuitry (rather than to one side of the IC 1400, for example), thus reducing IC area.

As should be appreciated, while the examples of BCL and FCL usage set forth above have generally been in the context of ICs fabricated using an SLT process, BCL and FCL structures (including FCL CAS-gated FETs) and TBC's may also be used in ICs fabricated using a DLT process.

Benefits of Fine Conductive Line CAS-gates

The fine-line fingers of FCL CAS-gates more fully control leakage and threshold voltage of a FET, without the increased C_{OFF} or drain capacitance of the larger RDL CAS-gate structure shown in FIG. 9. FCL CAS-gates thus avoid the complexity of the capacitive compensation required for proper voltage division in a stack of FETs. FCL CAS-gates also reduce or eliminate CAS gate effects on nearby regions (including the source S and drain D) that may not need or benefit from a CAS gate, which generally results in a smaller harmonic degradation of RF signals. Further, FCL CAS-gates consume less IC area than RDL CAS-gates.

An FCL CAS-gate structure may also be used to dynamically vary the ON resistance R_{ON} and drain-source breakdown voltage BVdss (with V_{GS}=0) characteristics of a FET or stack of FETs. Further, applying a relatively high negative bias to CAS gate of FCL CAS-gated FETs results in a higher BVdss characteristic for the FET.

Another advantage of BCL regions and FCLs in general is that their conductivity mitigates the known backside oxide charging effect that occurs from an SLT or DLT process, thus providing charge stabilization.

Other BCL and FCL Uses

While the FCLs shown in FIGS. 10A-10C and 11-13 are illustrated as CAS gates, BCL regions and FCLs can be used for other functions and structures.

For example, the fine pitch of FCLs is quite suitable for fabricating backside lateral capacitors. Thus, as one instance, the interdigitated fingers of the FCLs shown in FIG. 10A may be fabricated such that the odd fingers 1012a, 1012c, 1012e, 1012g are connected together (e.g., at the M1 level through corresponding TBC's 1014a, 1014c, 1014e, 1014g) as a first polarity capacitor plate, and the even fingers 1012b, 1012d, 1012f are similarly connected together as a second polarity capacitor plate. Further, since the backside on which BCL regions are fabricated may be subjected to additional process steps, including the creation of multiple parallel spaced-apart backside conductive layers, second and subsequent FCL lateral capacitors may be fabricated in a stacked manner in relation to a first FCL lateral capacitor, and like-polarity plates connected (e.g., by backside vias), so as to increase the capacitive density of the capacitor structure. When multiple parallel BCLs are available, parallel-plate (rather than lateral) capacitors can also be formed. Moreover, the plates of one or more stacked FCL lateral capacitors or BCL parallel-plate capacitors may be coupled via TBC's to like-polarity plates of vertically-aligned (through the BOX layer 104) capacitors fabricated in the conductive interconnect levels (e.g., M1-Mx) on the front side of an IC, thereby increasing capacitance without consuming additional die area.

FCL lateral capacitors and BCL parallel-plate capacitors give a designer the ability to add capacitance in an IC designer without adding surface area to the IC. For example, BCL and/or FCL based capacitors can be formed and coupled to nearby FCL CAS-gate FETs to provide capacitive compensation for a FET stack without consuming additional die area.

Backside inductors may also be fabricated from FCLs, such as by forming an FCL planar spiral and connecting one or more nodes along the spiral to other components, or forming an FCL transmission line from FCL segments configured as an FCL coplanar waveguide. Mutually-coupled inductors may be fabricated from FCLs formed in parallel BCLs, such as by forming a first FCL planar spiral in a first BCL in overlapping, spaced-apart relationship to a second FCL planar spiral in a second BCL.

As noted above, the combination of BCL regions/FCLs, TBC's, and front side conductive connections (e.g., through the conductive interconnect levels M1-Mx) allows fabrication of resistors.

As may be appreciated from the above description, TBC's enable ohmic or non-ohmic contact between circuitry on both sides of the BOX layer 104 (i.e., on both sides of an IC die), creating options for additional circuit elements. Thus, FCL lateral capacitors, BCL parallel-plate capacitors, FCL inductors, and/or FCL/TBC based resistors may be connected to other components (e.g., FETs, resistors, inductors, and/or capacitors) on the backside and/or on the front side (through TBC's) of an IC. For example, an FCL/TBC based resistor may be directly coupled to a capacitor (e.g., an FCL lateral capacitor or a front side capacitor) to create an RC filter element. Similarly, RL, LC, and RCL circuits may be created, in simple or complex arrangements, using a combination of BCL regions/FCL and TBC connections and components.

The combination of BCL regions/FCLs, TBC's, and front side conductive connections also enables increased design flexibility in routing voltage and power distribution pathways, since both sides of an IC die may be used for conductive pathways.

Another use of BCL regions and/or FCLs is to create a grounded plane or pattern on the backside of an IC that is aligned with respect to an inductor (e.g., a spiral structure) in one of the conductive interconnect levels M1-Mx so as to function as a ground shield for the inductor.

As another option, the dielectric (e.g., ILD) between adjacent FCLs can be removed (or never formed), creating essentially a conductive pillar or line that may be used for bonding or attachment of bumps for packaging. Similarly, BCL regions can be formed to use for bonding or attachment of bumps for packaging. Accordingly, since TBC's can be used to connect BCL regions and FCLs to elements in the active layer 106 and/or circuit elements in the conductive interconnect levels M1-Mx, some or all electrical contacts between the IC and off-chip circuitry can be made from the “new top” of the post-SLT IC structure.

Applications and Methods

For the sake of illustration, the example embodiments utilizing FCL CAS-gates have been a stack of transistors such as may be used for RF switches or amplifiers. However, FCL CAS-gates may be used with individual FETS, and, as FIG. 14 illustrates, FCL CAS-gates may be used with RF circuitry and with non-RF circuitry, and in either case, such circuitry may be analog or digital circuitry.

As noted above, CAS-gates may be used to individually adjust the threshold voltage V_{T} of a group of FETs, which is particularly useful in analog-to-digital (A/D) or digital-to-analog (D/A) converter circuits. For example, historically, high-speed flash A/D converter circuits have been fabricated as an array of FETs which are processed through complex and expensive equipment (such as focused ion beams) to slightly adjust the threshold voltage of each FET relative to other (usually adjacent) FETs in the array, so that each FET conducts at a different level of applied voltage. In contrast, the current invention can be used to implement a high-speed flash A/D converter by fabricating an array or stack of essentially identical CAS-gated FETs, and then use a voltage ladder to bias the CAS-gates with different voltage values. This approach leads to otherwise essentially identical CAS-gated FETs exhibiting different threshold voltages V_{T} as a function of the control voltage applied to their respective CAS gates such that each CAS-gated FET conducts at a different level of applied voltage. Accordingly, such embodiments avoid having to apply the complex and expensive equipment of conventional designs to adjust the threshold voltage of each FET individually.

IC wafers fabricated using an SLT process may have thermal issues, specifically, extracting heat from FETs through the SLT handle wafer 204 (especially if the handle wafer is of a dielectric material with poor thermal properties). Using BCL regions and/or FCLs and TBC's (alone or in conjunction with the conductive interconnect levels M1-Mx), a primary path for thermal extraction may be established through these thermally conductive elements. For example, one or more TBC's may be situated near a FET and thermally coupled to the FET (but electrically isolated from the FET). Alternatively, or in addition, portions of a conductive interconnect level (e.g., M1) may be situated near a FET and thermally coupled to the FET (but again, electrically isolated from the FET). Heat generated by the FET will be thermally coupled to any nearby TBC's and conveyed to BCL regions or FCLs in contact with those TBC's on the opposite side of the BOX layer 104. Similarly, heat generated by the FET will be thermally coupled to any nearby conductive interconnect level and conveyed through connected TBC's to BCL regions or FCLs in contact with the TBC's on the opposite side of the BOX layer 104. The heat may then be conveyed to packaging bumps and packaging heat sinks thermally coupled to such BCL regions/FCLs. Other examples of such primary thermal extraction paths are described in U.S. Pat. No. 9,960,098, issued May 1, 2018, entitled “Systems and Methods for Thermal Conduction Using S-Contacts”. Such thermal extraction structures would be particularly beneficial for high power dissipation circuits such as power amplifiers, high-speed digital circuitry, and high-power analog circuits.

Notably, combining BCL regions/FCLs and TBC's with FET-based IC circuitry (particularly CMOS FET IC circuitry) enables FCL CAS-gated FETS, various combinations of complex circuitry formed on both sides of a BOX layer 104, complex voltage and power distribution pathways, and thermal extraction, all while reusing essentially the same area as the original FET-based IC circuitry.

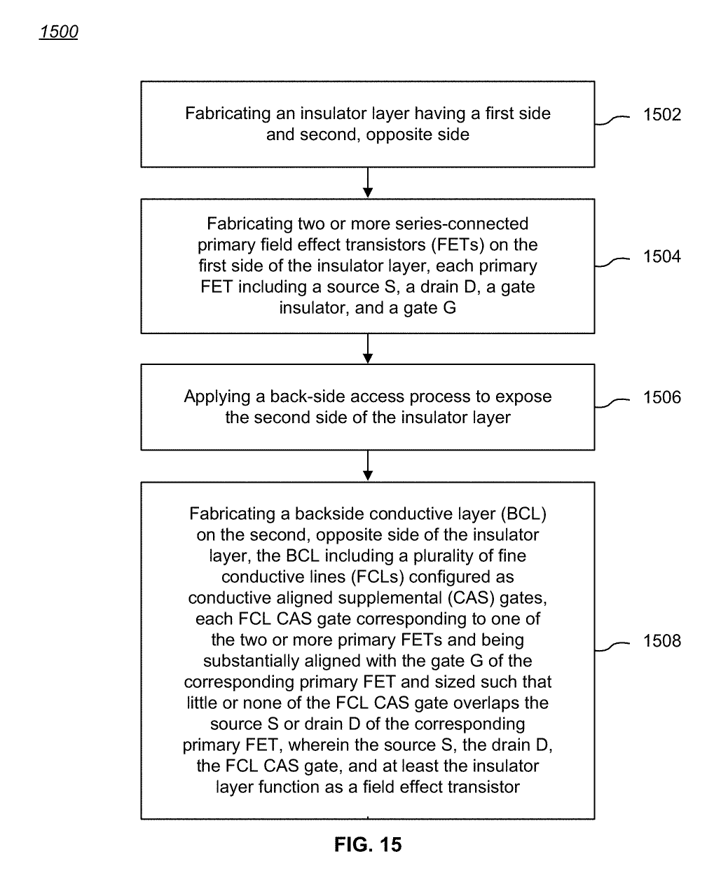

Another aspect of the invention includes methods for fabricating an integrated circuit structure having FCL CAS-gated FETs. For example, FIG. 15 is a process flow diagram 1500 of a first method for fabricating an integrated circuit structure having FCL CAS-gated FETs. In this example, the method includes: fabricating an insulator layer having a first side and second, opposite side (Block 1502); fabricating two or more series-connected primary field effect transistors (FETs) on the first side of the insulator layer, each primary FET including a source S, a drain D, a gate insulator, and a gate G (Block 1504); applying a back-side access process to expose the second side of the insulator layer (Block 1506); and fabricating a backside conductive layer (BCL) on the second, opposite side of the insulator layer, the BCL including a plurality of fine conductive lines (FCLs) configured as conductive aligned supplemental (CAS) gates, each FCL CAS gate corresponding to one of the two or more primary FETs and being substantially aligned with the gate G of the corresponding primary FET and sized such that little or none of the FCL CAS gate overlaps the source S or drain D of the corresponding primary FET, wherein the source S, the drain D, the FCL CAS gate, and at least the insulator layer function as a field effect transistor (Block 1508).

Other aspects of the method of FIG. 15 may include one or more of the following: wherein the gates G of the two or more primary FETs and the corresponding FCL CAS gates are arrayed in parallel; fabricating at least one conductive interconnect level on the first side of the insulator layer and fabricating at least one electrically conductive contact connected to the at least one interconnect level and to at least one FCL CAS gate through the insulator layer; wherein the gates G of the two or more primary FETs and the corresponding FCL CAS gates are arrayed in parallel, each FCL CAS gate is coupled to a corresponding electrically conductive contact, and FCL CAS gates are offset along their length with respect to the electrically conductive contacts of adjacent FCL CAS gates; wherein the gates G of the two or more primary FETs and the corresponding FCL CAS gates are arrayed in parallel, each FCL CAS gate is coupled to a corresponding electrically conductive contact, and a width of the FCL CAS gates is less than a width of the electrically conductive contacts of adjacent FCL CAS gates; wherein the gates G of the two or more primary FETs and the corresponding FCL CAS gates are arrayed in parallel, and at least two FCL CAS gates are connected through a common electrically conductive contact; fabricating at least one lateral capacitor formed by interdigitated FCLs; fabricating at least one parallel-plate capacitor formed by at least two parallel, spaced-apart BCLs; fabricating at least one inductor formed by one of an FCL planar spiral or an FCL coplanar waveguide; fabricating at least one resistor, including: fabricating at least one conductive interconnect level on the first side of the insulator layer, fabricating at least one BCL region on the second side of the insulator layer, and fabricating at least one resistive contact electrically connected between the at least one conductive interconnect level and the at least one BCL region through the insulator layer.

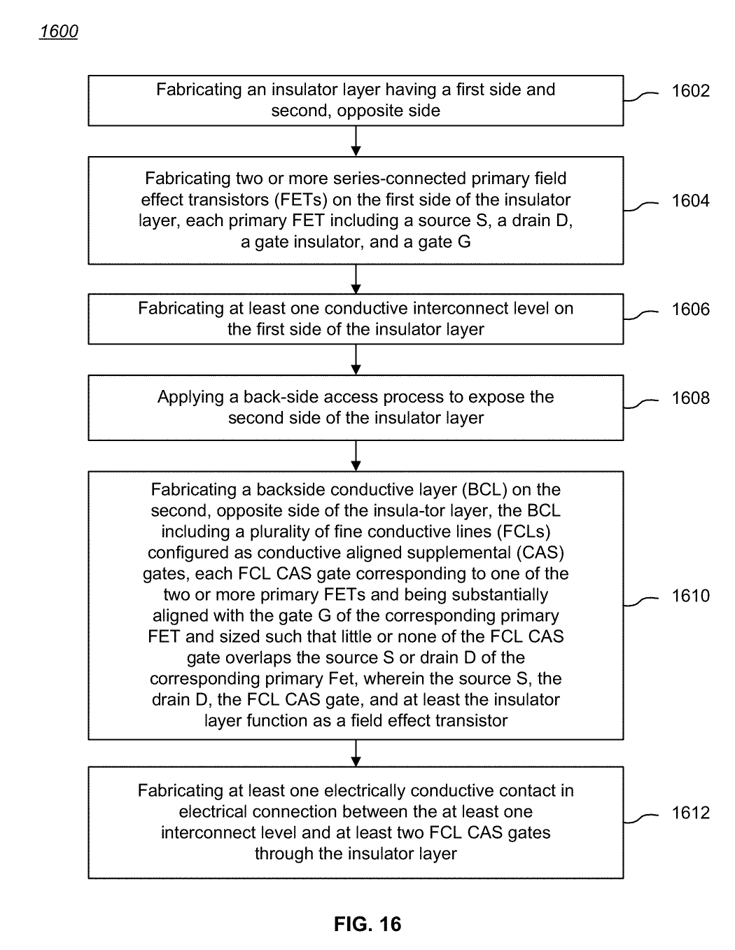

As another example, FIG. 16 is a process flow diagram 1600 of a second method for fabricating an integrated circuit structure having FCL CAS-gated FETs. In this example, the method includes: fabricating an insulator layer having a first side and second, opposite side (Block 1602); fabricating two or more series-connected primary field effect transistors (FETs) on the first side of the insulator layer, each primary FET including a source S, a drain D, a gate insulator, and a gate G (Block 1604); fabricating at least one conductive interconnect level on the first side of the insulator layer (Block 1606); applying a back-side access process to expose the second side of the insulator layer (Block 1608); (e) fabricating a backside conductive layer (BCL) on the second, opposite side of the insulator layer, the BCL including a plurality of fine conductive lines (FCLs) configured as conductive aligned supplemental (CAS) gates, each FCL CAS gate corresponding to one of the two or more primary FETs and being substantially aligned with the gate G of the corresponding primary FET and sized such that little or none of the FCL CAS gate overlaps the source S or drain D of the corresponding primary FET, wherein the source S, the drain D, the FCL CAS gate, and at least the insulator layer function as a field effect transistor (Block 1610); and fabricating at least one electrically conductive contact in electrical connection between the at least one interconnect level and at least two FCL CAS gates through the insulator layer (Block 1612).

Other aspects of the method of FIG. 16 may include: wherein the at least one electrically conductive contact is connected between the at least one interconnect level and the plurality of FCL CAS gates through the insulator layer.

Fabrication Technologies & Options

The term “MOSFET”, as used in this disclosure, means any field effect transistor (FET) with an insulated gate and comprising a metal or metal-like, insulator, and semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

With respect to the figures referenced in this disclosure, note that the dimensions for the various elements are not to scale; some dimensions have been greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

As should be readily apparent to one of ordinary skill in the art, various embodiments of the invention can be implemented to meet a wide variety of specifications. Unless otherwise noted above, selection of suitable component values is a matter of design choice and various embodiments of the invention may be implemented in any suitable integrated circuit (IC) technology (including but not limited to MOSFET structures) having characteristics similar to those described above. Integrated circuit embodiments may be fabricated using any suitable substrates and processes, including but not limited to silicon-on-insulator (SOI) and silicon-on-sapphire (SOS). The inventive concepts described above are particularly useful with a semiconductor-on-insulator-based fabrication process (including SOI, germanium-on-insulator, silicon-on-glass, and SOS), and with fabrication processes having similar characteristics. Fabrication in CMOS with compatible semiconductor-on-insulator processes enables circuits with low power consumption, the ability to withstand high power signals during operation due to FET stacking, good linearity, and high frequency operation (i.e., radio frequencies up to and exceeding 50 GHz). Monolithic IC implementation is particularly useful since parasitic capacitances generally can be kept low (or at a minimum, kept uniform across all units, permitting them to be compensated) by careful design.

Voltage levels may be adjusted, or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

Conclusion

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1-36. (canceled)

37. An integrated circuit structure including:
(a) an insulator layer having a first side and second, opposite side;
(b) two or more series-connected primary field effect transistors (FETs) fabricated on the first side of the insulator layer, each primary FET including a source S, a drain D, a gate insulator, and a gate G; and
(c) a backside conductive layer (BCL) fabricated on the second, opposite side of the insulator layer after the second, opposite side of the insulator layer becomes accessible by application of a backside access process, the BCL including a plurality of fine conductive lines (FCLs) configured as conductive aligned supplemental (CAS) gates, each FCL CAS gate corresponding to one of the two or more primary FETs and being substantially aligned with the gate G of the corresponding primary FET and sized such that little or none of the FCL CAS gate overlaps the source S or drain D of the corresponding primary FET, wherein the source S, the drain D, the FCL CAS gate, and at least the insulator layer function as a field effect transistor.

38. The invention of claim 37, wherein the gates G of the two or more primary FETs and the corresponding FCL CAS gates are arrayed in parallel.

39. The invention of claim 37, further including at least one conductive interconnect level on the first side of the insulator layer and at least one electrically conductive contact connected to the at least one interconnect level and to at least one FCL CAS gate through the insulator layer.

40. The invention of claim 39, wherein the gates G of the two or more primary FETs and the corresponding FCL CAS gates are arrayed in parallel, each FCL CAS gate is coupled to a corresponding electrically conductive contact, and FCL CAS gates are offset along their length with respect to the electrically conductive contacts of adjacent FCL CAS gates.

41. (canceled)

42. The invention of claim 39, wherein the gates G of the two or more primary FETs and the corresponding FCL CAS gates are arrayed in parallel, and at least two FCL CAS gates are connected through a common electrically conductive contact.

43. The invention of claim 37, further including at least one lateral capacitor formed by interdigitated FCLs.

44. (canceled)

45. The invention of claim 37, further including at least one inductor formed by one of an FCL planar spiral or an FCL coplanar waveguide.

46. The invention of claim 37, further including at least one resistor comprising:
(a) at least one conductive interconnect level on the first side of the insulator layer;
(b) at least one BCL region on the second side of the insulator layer; and
(c) at least one resistive contact electrically connected between the at least one conductive interconnect level and the at least one BCL region through the insulator layer.

47. An integrated circuit structure including:
(a) an insulator layer having a first side and second, opposite side;
(b) two or more series-connected primary field effect transistors (FETs) fabricated on the first side of the insulator layer, each primary FET including a source S, a drain D, a gate insulator, and a gate G;
(c) at least one conductive interconnect level fabricated on the first side of the insulator layer;
(d) a backside conductive layer (BCL) fabricated on the second, opposite side of the insulator layer after the second, opposite side of the insulator layer becomes accessible by application of a backside access process, the BCL including a plurality of fine conductive lines (FCLs) configured as conductive aligned supplemental (CAS) gates, each FCL CAS gate corresponding to one of the two or more primary FETs and being substantially aligned with the gate G of the corresponding primary FET and sized such that little or none of the FCL CAS gate overlaps the source S or drain D of the corresponding primary FET, wherein the source S, the drain D, the FCL CAS gate, and at least the insulator layer function as a field effect transistor; and
(e) at least one electrically conductive contact connected between the at least one interconnect level and at least two FCL CAS gates through the insulator layer.

48. The invention of claim 47, wherein the at least one electrically conductive contact is connected between the at least one interconnect level and the plurality of FCL CAS gates through the insulator layer.

49. A method for fabricating an integrated circuit structure, including:
(a) fabricating an insulator layer having a first side and second, opposite side;
(b) fabricating two or more series-connected primary field effect transistors (FETs) on the first side of the insulator layer, each primary FET including a source S, a drain D, a gate insulator, and a gate G;
(c) applying a back-side access process to expose the second side of the insulator layer; and
(d) fabricating a backside conductive layer (BCL) on the second, opposite side of the insulator layer, the BCL including a plurality of fine conductive lines (FCLs) configured as conductive aligned supplemental (CAS) gates, each FCL CAS gate corresponding to one of the two or more primary FETs and being substantially aligned with the gate G of the corresponding primary FET and sized such that little or none of the FCL CAS gate overlaps the source S or drain D of the corresponding primary FET, wherein the source S, the drain D, the FCL CAS gate, and at least the insulator layer function as a field effect transistor.

50. The method of claim 49, wherein the gates G of the two or more primary FETs and the corresponding FCL CAS gates are arrayed in parallel.

51. The method of claim 49, further including fabricating at least one conductive interconnect level on the first side of the insulator layer and fabricating at least one electrically conductive contact connected to the at least one interconnect level and to at least one FCL CAS gate through the insulator layer.

52. The method of claim 51, wherein the gates G of the two or more primary FETs and the corresponding FCL CAS gates are arrayed in parallel, each FCL CAS gate is coupled to a corresponding electrically conductive contact, and FCL CAS gates are offset along their length with respect to the electrically conductive contacts of adjacent FCL CAS gates.

53. (canceled)

54. The method of claim 51, wherein the gates G of the two or more primary FETs and the corresponding FCL CAS gates are arrayed in parallel, and at least two FCL CAS gates are connected through a common electrically conductive contact.

55. The method of claim 49, further including fabricating at least one lateral capacitor formed by interdigitated FCLs.

56. (canceled)

57. The method of claim 49, further including fabricating at least one inductor formed by one of an FCL planar spiral or an FCL coplanar waveguide.

58. The method of claim 49, further including fabricating at least one resistor, including:
(a) fabricating at least one conductive interconnect level on the first side of the insulator layer;
(b) fabricating at least one BCL region on the second side of the insulator layer; and
(c) fabricating at least one resistive contact electrically connected between the at least one conductive interconnect level and the at least one BCL region through the insulator layer.

59. A method of fabricating an integrated circuit structure, including:
(a) fabricating an insulator layer having a first side and second, opposite side;
(b) fabricating two or more series-connected primary field effect transistors (FETs) on the first side of the insulator layer, each primary FET including a source S, a drain D, a gate insulator, and a gate G;
(c) fabricating at least one conductive interconnect level on the first side of the insulator layer;
(d) applying a back-side access process to expose the second side of the insulator layer;
(e) fabricating a backside conductive layer (BCL) on the second, opposite side of the insulator layer, the BCL including a plurality of fine conductive lines (FCLs) configured as conductive aligned supplemental (CAS) gates, each FCL CAS gate corresponding to one of the two or more primary FETs and being substantially aligned with the gate G of the corresponding primary FET and sized such that little or none of the FCL CAS gate overlaps the source S or drain D of the corresponding primary FET, wherein the source S, the drain D, the FCL CAS gate, and at least the insulator layer function as a field effect transistor; and
(f) fabricating at least one electrically conductive contact in electrical connection between the at least one interconnect level and at least two FCL CAS gates through the insulator layer.

60. The invention of claim 59, wherein the at least one electrically conductive contact is connected between the at least one interconnect level and the plurality of FCL CAS gates through the insulator layer.
